(19) United States
(12) Patent Application Publication
(10) Pub. No.: US 2012/0181518 A1
(43) Pub. Date: Jul. 19, 2012

(54) ORGANIC ELECTROLUMINESCENCE DEVICE

(75) Inventors: Toshinari OGIWARA, Sodegaura-shi (JP); Kazuki Nishimura, Sodegaura-shi (JP)

(73) Assignee: Idemitsu Kosan Co., Ltd., Chiyoda-ku (JP)

(21) Appl. No.: 13/341,225

(22) Filed: Dec. 30, 2011

(30) Foreign Application Priority Data
Jan. 5, 2011 (JP) 2011-000871

(51) Int. Cl. H01L 51/54

(52) U.S. Cl. 257/40; 257/E51.026

(57) ABSTRACT

An organic electroluminescence device includes: an anode; a cathode; and at least hole transporting layer and emitting layer both provided between the anode and the cathode. The hole transporting layer contains a hole transporting material. The emitting layer is adjacent to the hole transporting layer, and contains a first host material, a second host material and a phosphorescent dopant material. An ionization potential IP(HT) of the hole transporting material, an ionization potential IP(h1) of the first host material and an ionization potential IP(h2) of the second host material satisfy a relationship represented by an expression (1) below.

IP(h1)>IP(HT)>IP(h2) Expression (1)

The entire disclosure of Japanese Patent Application No. 2011-000871, filed Jan. 5, 2011 is expressly incorporated by reference herein.

### BACKGROUND OF THE INVENTION

1. Field of the Invention

The present invention relates to an organic electroluminescence device (hereinafter abbreviated as organic EL device as needed).

2. Description of Related Art

An organic EL device is a self-emitting device that is based on a principle according to which, with an electric filed applied, an emitting material emits light by recombination energy caused by holes injected from an anode and electrons injected from a cathode.

Organic EL devices formed from organic materials have been vigorously studied since a report on a low voltage-driven organic EL device formed by laminating layers was made by C. W. Tang et al. of Eastman Kodak Company.

Further, a phosphorescent organic EL device using a phosphorescent material as an emitting layer has been suggested. The phosphorescent organic EL device uses excited states of the phosphorescent material, i.e., a singlet state and a triplet state, to achieve a high luminous efficiency. When electrons and holes are recombined in an emitting layer, it is presumed that singlet excitons and triplet excitons are produced at a rate of 1:3 due to a difference in spin multiplicity. Thus, a device using a phosphorescent material presumably achieves a three to four times higher luminous efficiency than a device using only a fluorescent material.

In order to further improve a luminous efficiency, an organic EL device containing at least two host materials in an emitting layer has been suggested (see, for instance, Patent Literature 1: JP-A-2006-270053, Patent Literature 2: JP-A-2007-134677).

Each of the organic EL devices disclosed in Patent Literature 1 and Patent Literature 2 includes a hole-transporting host material and an electron-transporting host material in an emitting layer. By containing these two host materials, a balance between holes and electrons injected into the emitting layer is controlled to prevent deterioration of drive durability. However, in addition to the hole-transporting host material and the electron-transporting host material, the organic EL device disclosed in Patent Literature 1 contains at least two phosphorescent dopant materials, and the energy level such as electron affinity and ionization potential thereof needs to fall within a specific range. Thus, it is difficult to select the materials. The organic EL device disclosed in Patent Literature 2 requires a hole-transporting intermediate layer formed only from a hole-transporting host material and provided between the hole transporting layer and the emitting layer to reduce hole injection barrier against the emitting layer, and requires an electron-transporting intermediate layer formed only from an electron-transporting host material and provided between the electron transporting layer and the emitting layer to reduce electron injection barrier against the emitting layer. In addition, both organic EL devices disclosed in these Patent Literatures exhibit an unsatisfactory luminous efficiency.

### SUMMARY OF THE INVENTION

An object of the invention is to provide an organic electroluminescence device with a high luminous efficiency.

As a result of concentrated studies for achieving the above object, the inventors have found that when an emitting layer contains a first host material in combination with a second host material having a specific ionization potential, holes are trapped in the second host material, thereby improving the carrier balance in the emitting layer to improve the luminous efficiency. The invention is achieved based on the above findings.

According to an aspect of the invention, an organic electroluminescence device includes: an anode; a cathode; and at least hole transporting layer and emitting layer both being provided between the anode and the cathode, in which the hole transporting layer contains a hole transporting material, the emitting layer is provided adjacent to the hole transporting layer, and contains a first host material, a second host material and a phosphorescent dopant material, and an ionization potential IP(HT) of the hole transporting material, an ionization potential IP(h1) of the first host material and an ionization potential IP(h2) of the second host material satisfy a relationship represented by an expression 1 below.

IP(h1)>IP(HT)>IP(h2) Expression (1)

In the above aspect, it is preferable that a hole mobility of the second host material is higher than an electron mobility thereof.

In the above aspect, it is preferable that the second host material is represented by a formula (1) below.

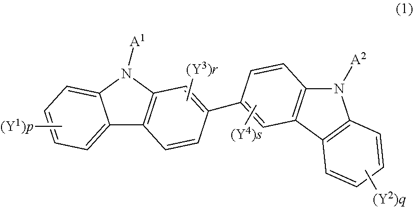

In the formula (1),

A¹ and A² each represent a substituted or unsubstituted aromatic hydrocarbon group having 6 to 30 ring carbon atoms, a substituted or unsubstituted heterocyclic group having 1 to 30 ring carbon atoms, or a group represented by a formula (2) below.

—X-A³ (2)

X is a single bond or a linking group, the linking group being a substituted or unsubstituted aromatic hydrocarbon group having 6 to 30 ring carbon atoms, a substituted or unsubstituted fused aromatic hydrocarbon group having 6 to 30 ring carbon atoms, a substituted or unsubstituted aromatic heterocyclic group having 2 to 30 ring carbon atoms, or a substituted or unsubstituted fused aromatic heterocyclic group having 2 to 30 ring carbon atoms.

A³ represents a substituted or unsubstituted nitrogen-containing heterocyclic group.

Y₁ to Y₄ each independently represent a hydrogen atom, a fluorine atom, a cyano group, a substituted or unsubstituted alkyl group having 1 to 20 carbon atoms, a substituted or unsubstituted alkoxy group having 1 to 20 carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 10 carbon atoms, a substituted or unsubstituted arylsilyl group having 6 to 30 carbon atoms, a substituted or unsubstituted aromatic hydrocarbon group having 6 to 30 ring carbon atoms, a substituted or unsubstituted fused aromatic hydrocarbon group having 6 to 30 ring carbon atoms, a substituted or unsubstituted aromatic heterocyclic group having 2 to 30 ring carbon atoms, a substituted or unsubstituted fused aromatic heterocyclic group having 2 to 30 ring carbon atoms, or a group represented by the formula (2).

Adjacent ones of Y¹ to Y⁴ are allowed to be bonded to each other to form a ring structure

Any one of A¹, A² and Y¹ to Y⁴ contains the group represented by the formula (2)

p and q each represent an integer of 1 to 4 and r and s each represent an integer of 1 to 3.

When each of p and q is an integer of 2 to 4 and each of r and s is an integer of 2 to 3, a plurality of Y¹ to Y⁴ are allowed to be the same or different.

In the above aspect, in the formula (1) representing the second host material, it is preferable that at least one of A¹ and A² is the group represented by the formula (2) and X of the formula (2) represents a single bond.

In the above aspect, in the formula (1) representing the second host material, it is preferable that A¹ is the group represented by the formula (2) and X of the formula (2) represents a single bond.

In the above aspect, it is preferable that the organic electroluminescence device further includes an electron injecting layer being provided between the anode and the cathode adjacently to the cathode, the electron injecting layer containing an organic metal complex.

In the above aspect, it is preferable that an emission peak wavelength of the phosphorescent dopant material falls within a range from 480 nm to 570 nm.

According to the above aspect of the invention, it is possible to provide an organic electroluminescence device with a high luminous efficiency.

### BRIEF DESCRIPTION OF THE DRAWINGS

FIG. 1 schematically shows an exemplary arrangement of an organic electroluminescence device according to an exemplary embodiment of the invention.

FIG. 2 is an energy diagram of a hole transporting layer and an emitting layer according to the exemplary embodiment.

FIG. 3A is an energy diagram of a hole transporting layer and an emitting layer of a typical organic electroluminescence device.

FIG. 3B is another energy diagram of the hole transporting layer and the emitting layer of the typical organic electroluminescence device.

### DETAILED DESCRIPTION OF PREFERRED EMBODIMENT(S)

An organic electroluminescence device according to an exemplary embodiment of the invention will be described below.

### Arrangement of Organic Electroluminescence Device

An arrangement of an organic electroluminescence device (hereinafter abbreviated as organic EL device) according to the exemplary embodiment will be described below.

Representative arrangement examples of the organic EL device according to the exemplary embodiment are as follows:

(1) anode/hole transporting layer/emitting layer/cathode;
(2) anode/hole transporting layer/emitting layer/electron injecting transporting layer/cathode; and
(3) anode/hole injecting layer/hole transporting layer/emitting layer/electron injecting transporting layer/cathode.

The “electron injecting/transporting layer (or electron injecting transporting layer)” herein means “at least one of electron injecting layer and electron transporting layer”.

Among the above arrangement examples, the arrangement (3), in particular, an arrangement having an electron injecting layer, is preferably usable, but the arrangement according to the exemplary embodiment is not limited thereto.

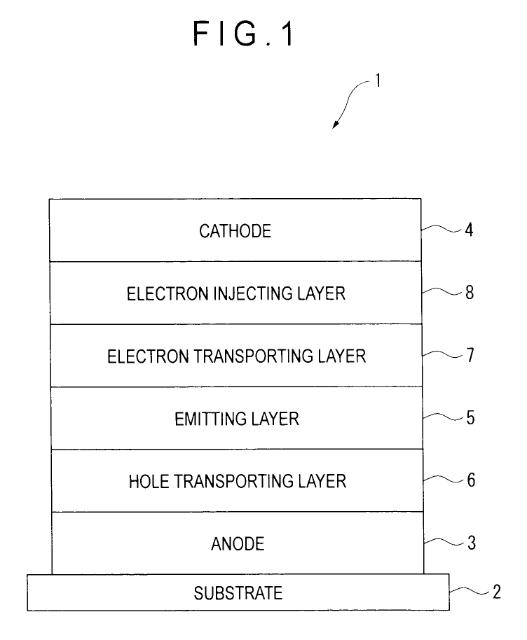

FIG. 1 shows an organic EL device 1 according to the exemplary embodiment.

The organic EL device 1 includes a transparent substrate 2, an anode 3, a cathode 4, a hole transporting layer 6, an emitting layer 5, an electron transporting layer 7 and an electron injecting layer 8.

The hole transporting layer 6, the emitting layer 5, the electron transporting layer 7, the electron injecting layer 8 and the cathode 4 are in this sequence layered on the anode 3.

### Substrate

The transparent substrate 2, which supports the organic EL device, is preferably a smooth substrate that transmits 50% or more of light in a visible region of 400 nm to 700 nm. Examples of such a substrate are a glass plate and a polymer plate.

For the glass plate, materials such as soda-lime glass, barium/strontium-containing glass, lead glass, aluminosilicate glass, borosilicate glass, barium borosilicate glass and quartz can be used.

For the polymer plate, materials such as polycarbonate resins, acryl resins, polyethylene terephthalate resins, polyether sulfide resins and polysulfone resins can be used.

### Anode and Cathode

The anode 3 of the organic EL device is used for injecting holes into the hole transporting layer or the emitting layer. It is effective that the anode has a work function of 4.5 eV or more.

Examples of a material for the anode are alloys of indium-tin oxide (ITO), tin oxide (NESA™), indium zinc oxide, gold, silver, platinum and copper.

The anode may be made by forming a thin film from these electrode substances by vapor deposition, sputtering or the like.

When light from the emitting layer is to be emitted through the anode, the anode preferably transmits more than 10% of the light in the visible region. Sheet resistance of the anode is preferably several hundreds Ω/sq. or lower. Although depending on the material of the anode, the thickness of the anode is typically in a range of 10 nm to 1 μm, preferably in a range of 10 nm to 200 nm.

The cathode 4, which injects electrons into the electron transporting layer or the emitting layer, is preferably formed of a material with a small work function.

Although a material for the cathode is subject to no specific limitation, examples of the material are indium, aluminum, magnesium, alloy of magnesium and indium, alloy of magnesium and aluminum, alloy of aluminum and lithium, alloy of aluminum, scandium and lithium, and alloy of magnesium and silver.

Like the anode, the cathode may be made by forming a thin film from the above substances by a method such as vapor deposition or sputtering. In the organic EL device, light may be emitted through the cathode.

### Hole Transporting Layer

The hole transporting layer 6, which transports holes to an emitting region, has a high hole mobility and a low ionization potential.

A hole transporting material for forming the hole transporting layer is preferably a material capable of transporting holes to the emitting layer with a low field intensity, an example of which is an aromatic amine compound. For instance, an aromatic amine derivative represented by the following formula (A1) is preferably usable.

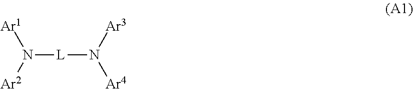

In the formula (A1), Ar¹ to Ar⁴ each represent one of the following:

an aromatic hydrocarbon group having 6 to 50 carbon atoms forming the aromatic ring (hereinafter referred to as ring carbon atoms);

a fused aromatic hydrocarbon group having 6 to 50 ring carbon atoms;

an aromatic heterocyclic group having 2 to 40 ring carbon atoms;

a fused aromatic heterocyclic group having 2 to 40 ring carbon atoms;

a group provided by bonding the aromatic hydrocarbon group and the aromatic heterocyclic group;

a group provided by bonding the aromatic hydrocarbon group and the fused aromatic heterocyclic group;

a group provided by bonding the fused aromatic hydrocarbon group and the aromatic heterocyclic group; and

a group provided by bonding the fused aromatic hydrocarbon group and the fused aromatic heterocyclic group.

The above aromatic hydrocarbon group, fused aromatic hydrocarbon group, aromatic heterocyclic group and fused aromatic heterocyclic group may be substituted.

In the formula (A1), L represents a linking group, examples of which are as follows:

a divalent aromatic hydrocarbon group having 6 to 50 ring carbon atoms;

a divalent fused aromatic hydrocarbon group having 6 to 50 ring carbon atoms;

a divalent aromatic heterocyclic group having 5 to 50 ring carbon atoms;

a divalent fused aromatic heterocyclic group having 5 to 50 ring carbon atoms; and

a divalent group provided by bonding two or more aromatic hydrocarbon groups or aromatic heterocyclic groups via the following:

a single bond;

an ether bond;

a thioether bond;

an alkylene group having 1 to 20 carbon atoms;

an alkenylene group having 2 to 20 carbon atoms; or

an amino group.

The above divalent aromatic hydrocarbon group, divalent fused aromatic hydrocarbon group, divalent aromatic heterocyclic group and divalent fused aromatic heterocyclic group may be substituted.

Examples of the compound represented by the formula (A1) are shown below. However, the compound is not limited thereto.

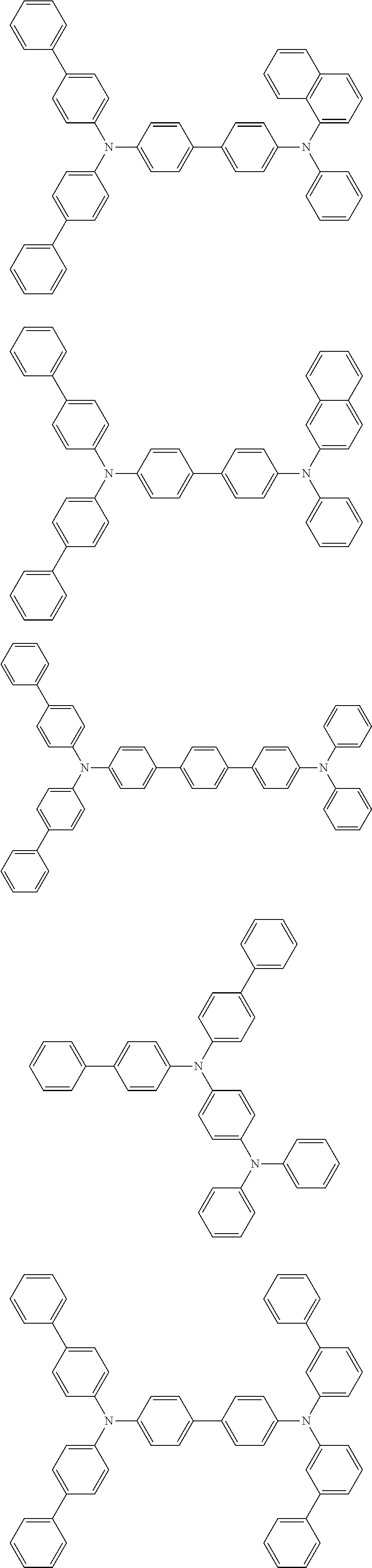

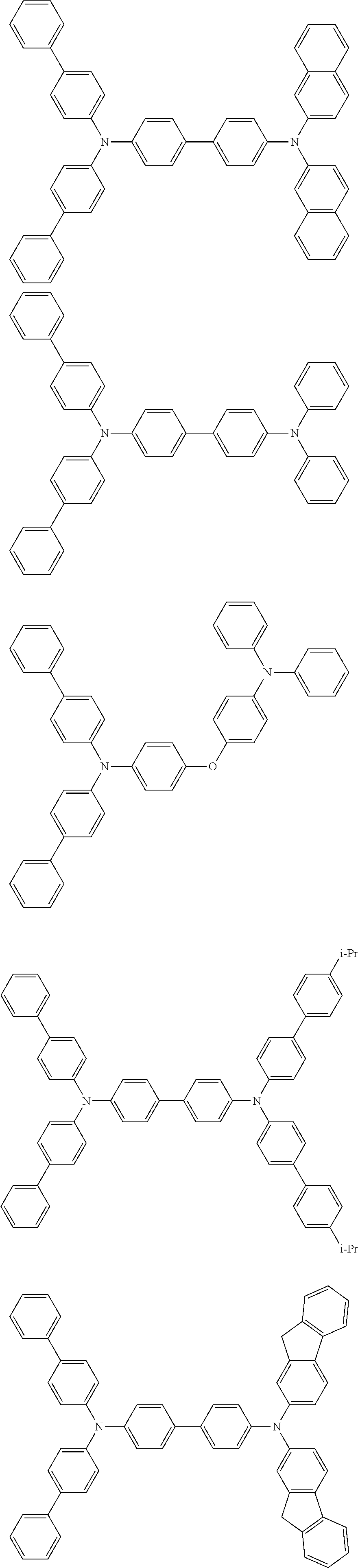

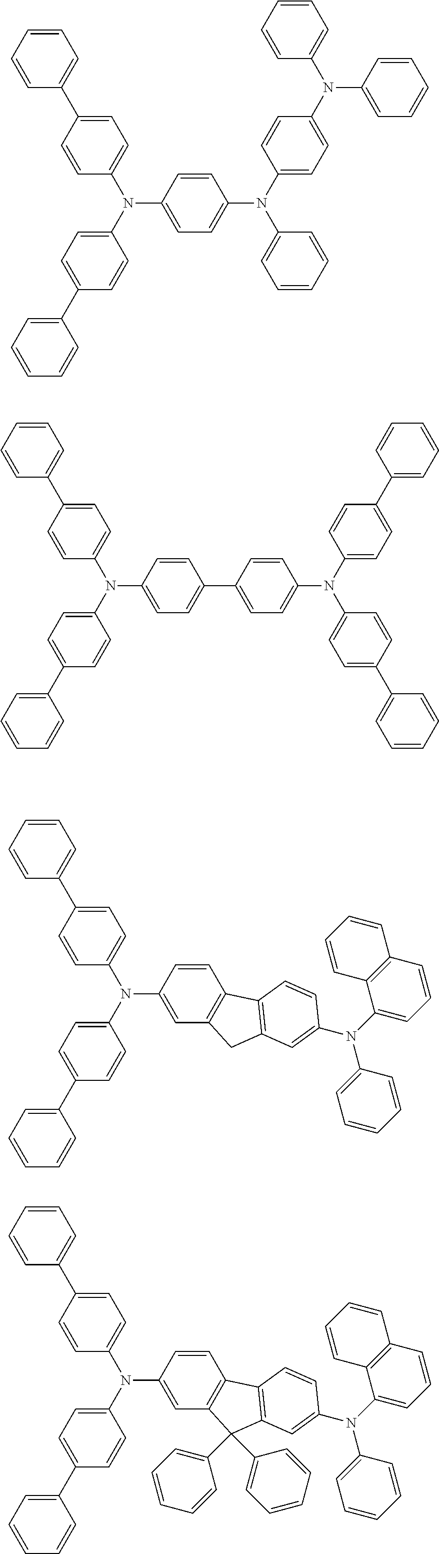

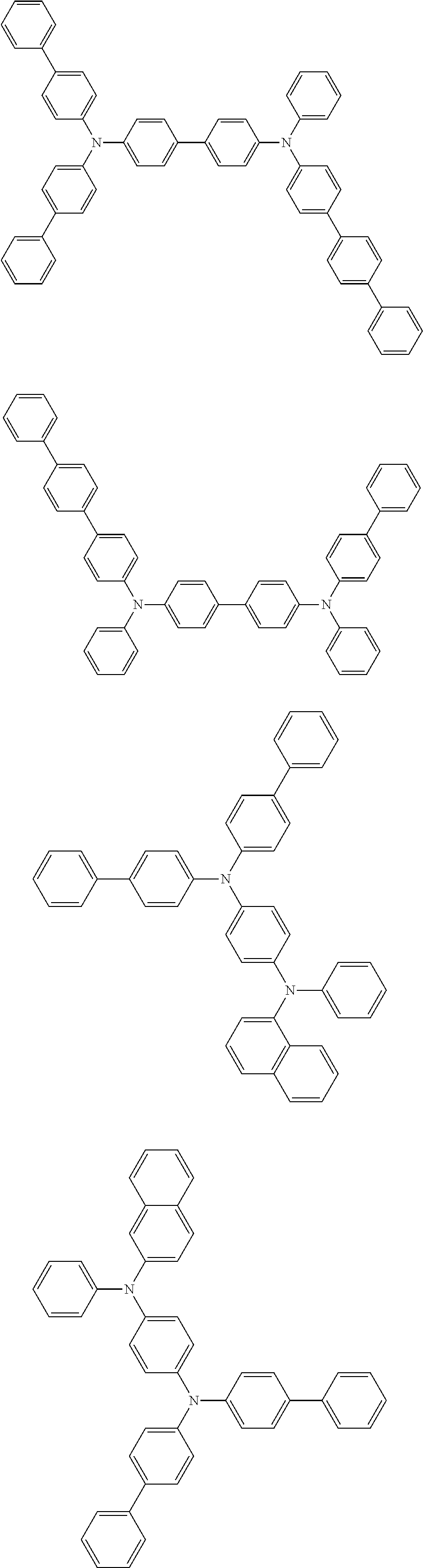

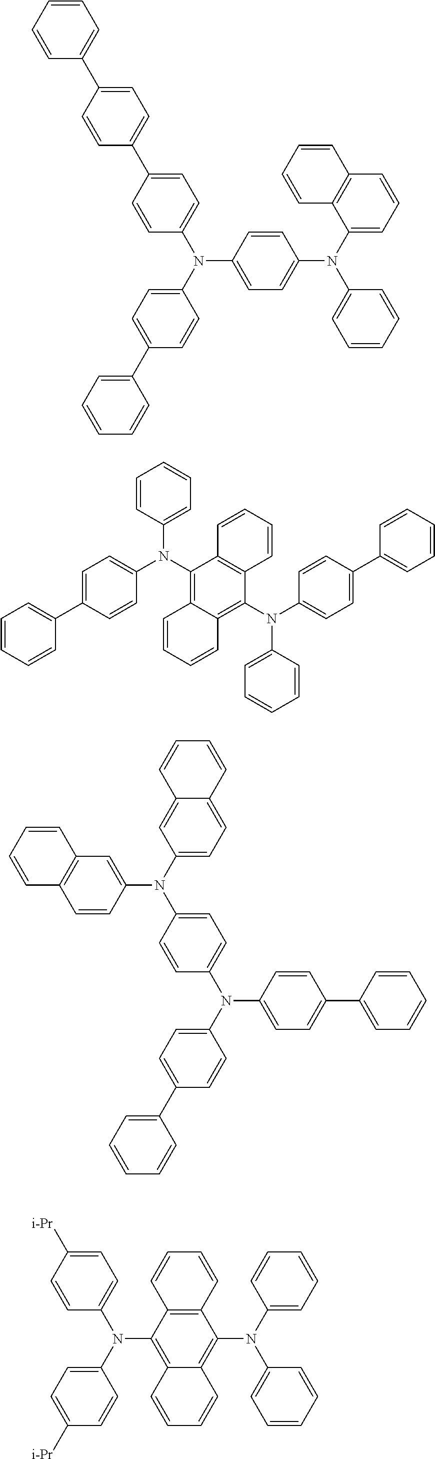

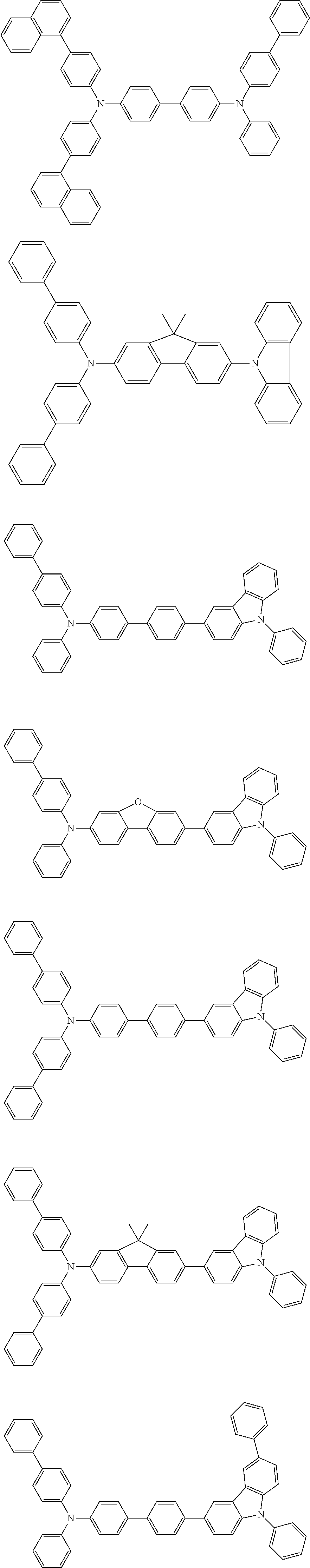

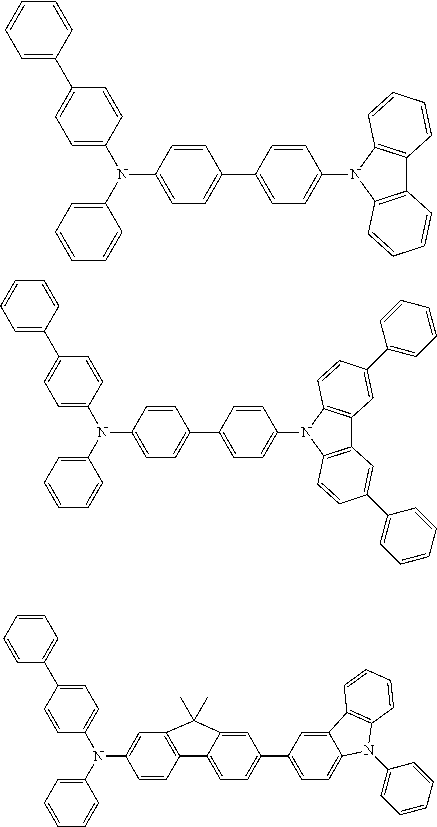

Aromatic amine represented by the following formula (A2) is also preferably usable for forming the hole transporting layer.

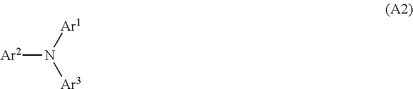

In the formula (A2), Ar¹ to Ar³ each represent the same as Ar¹ to Ar⁴ of the above formula (A1). Examples of the compound represented by the formula (A2) are shown below. However, the compound is not limited thereto.

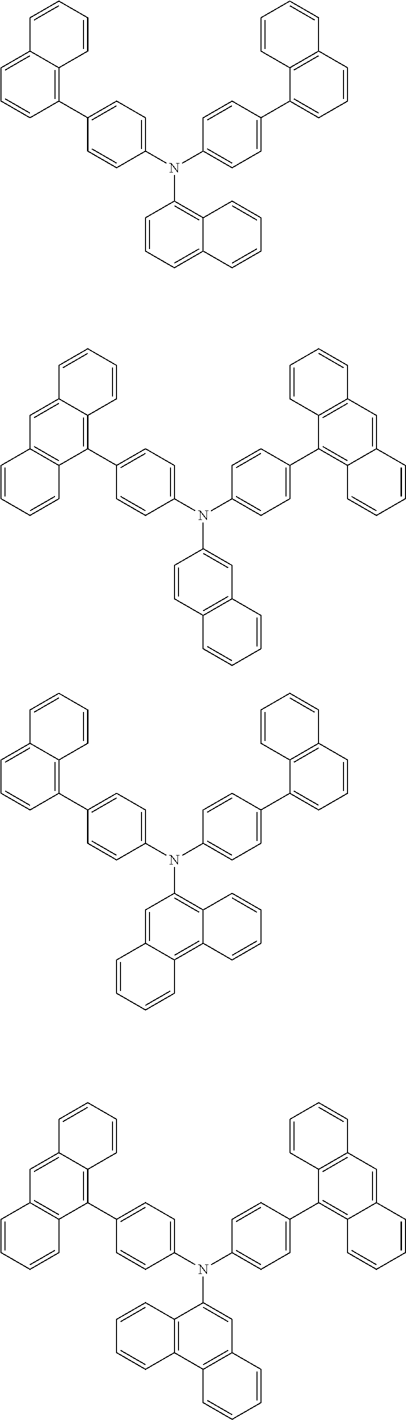

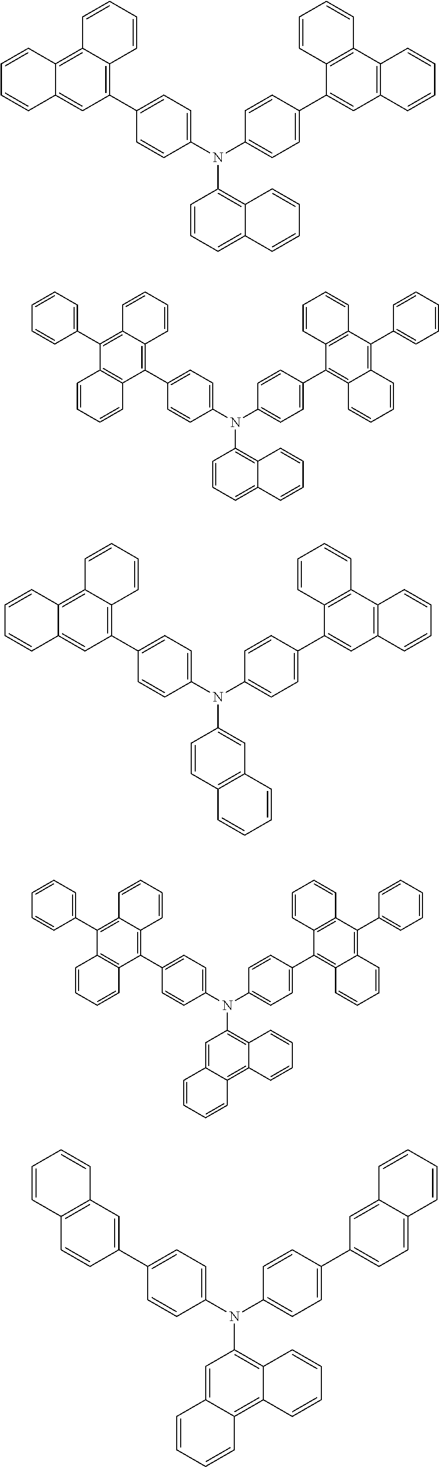

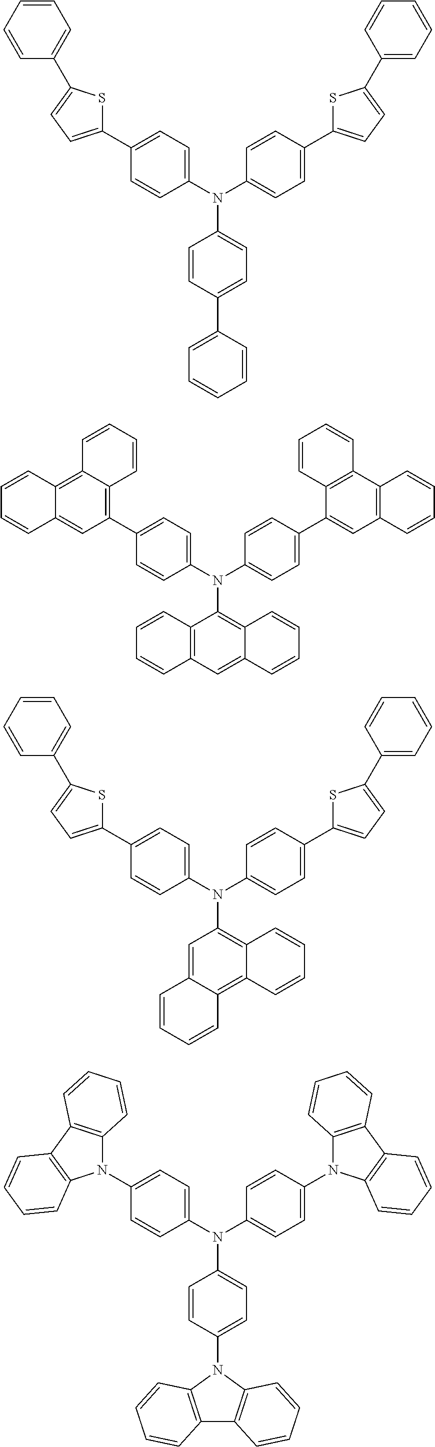

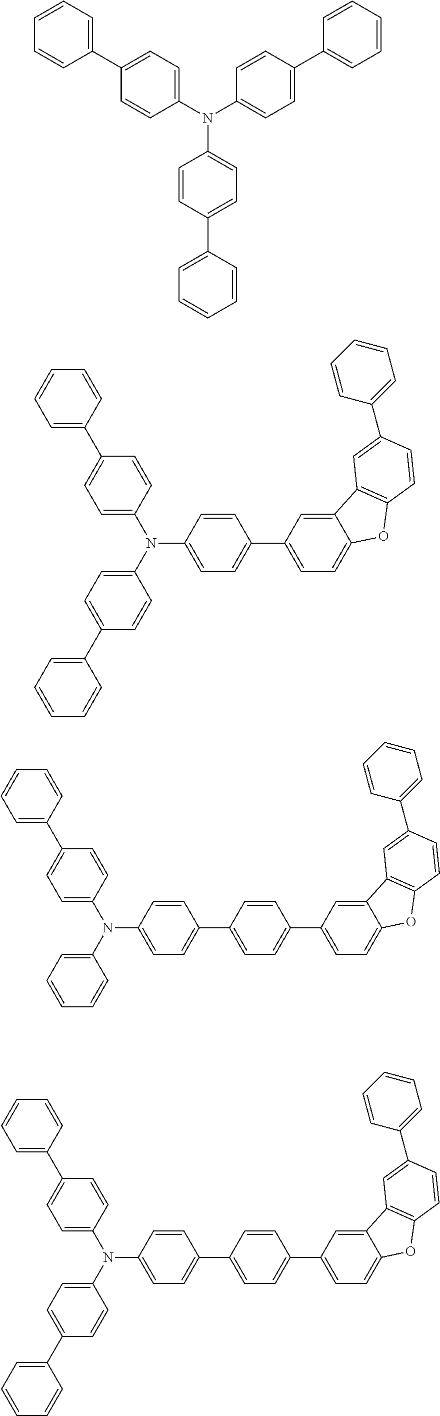

Although depending on a combination of a first host material and a second host material of the emitting layer (described later), an ionization potential IP(HT) of the hole transporting material preferably falls within a range from 5.3 eV to 5.9 eV.

### Emitting Layer

In the exemplary embodiment, the emitting layer 5 is layered on the hole transporting layer 6 and is adjacent thereto.

The emitting layer 5 contains a first host material, a second host material and a phosphorescent dopant material.

The first host material and the second host material are different compounds. The first host material is preferably contained at 50 mass % to 90 mass %. The second host material is preferably contained at 5 mass % to 50 mass %. The phosphorescent dopant material is contained at 0.1 mass % to 30 mass %.

The emitting layer 5 has a function for providing a condition for a recombination of electrons and holes to emit light.

The injectability of the holes may differ from that of the electrons and the transporting capabilities of the hole and the electrons (represented by the mobilities of the holes and the electrons) may differ from each other.

### Second Host Material

In the exemplary embodiment, an ionization potential IP(h2) of the second host material preferably satisfies a relationship represented by the following expression (2) with the ionization potential IP(HT) of the hole transporting material and an ionization potential IP(h1) of the first host material.

IP(h1)>IP(HT)>IP(h2) Expression (2)

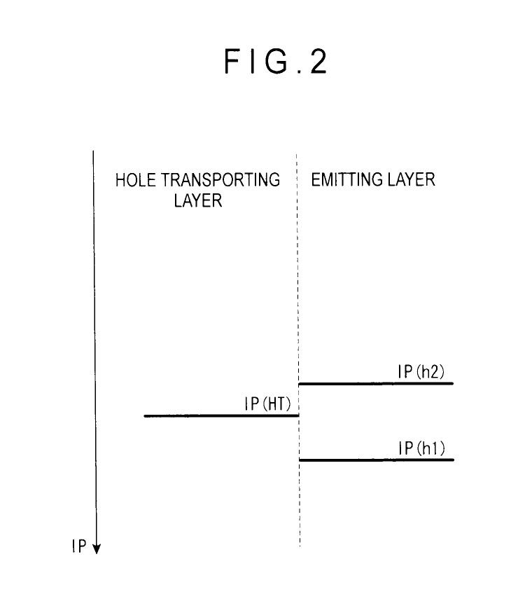

FIG. 2 shows the respective ionization potentials of these layers that satisfy the expression (2).

The ionization potential IP herein means energy required for removing electron(s) from a compound of the host material (i.e., energy required for ionization). The ionization potential is, for instance, a value measured by an ultraviolet-ray photoelectron spectrometer (AC-3, manufactured by Riken Keiki Co., Ltd.).

When the ionization potential IP(h2) of the second host material satisfies the expression (2), the second host material exhibits a hole-trapping property. In other words, due to the presence of the second host material having the low ionization potential IP(h2), holes injected from the IP(HT) of the hole transporting layer to the IP(h1) of the first host material are trapped by the IP(h2) of the second host material. Thus, when a large amount of holes are injected from an electrode to an emitting layer or a small amount of electrons are injected from an electrode to an emitting layer in an organic EL device, by providing the second host material satisfying the expression (2) to the emitting layer 5, the amount of holes in the emitting layer 5 in a hole excess state can be reduced to improve the carrier balance.

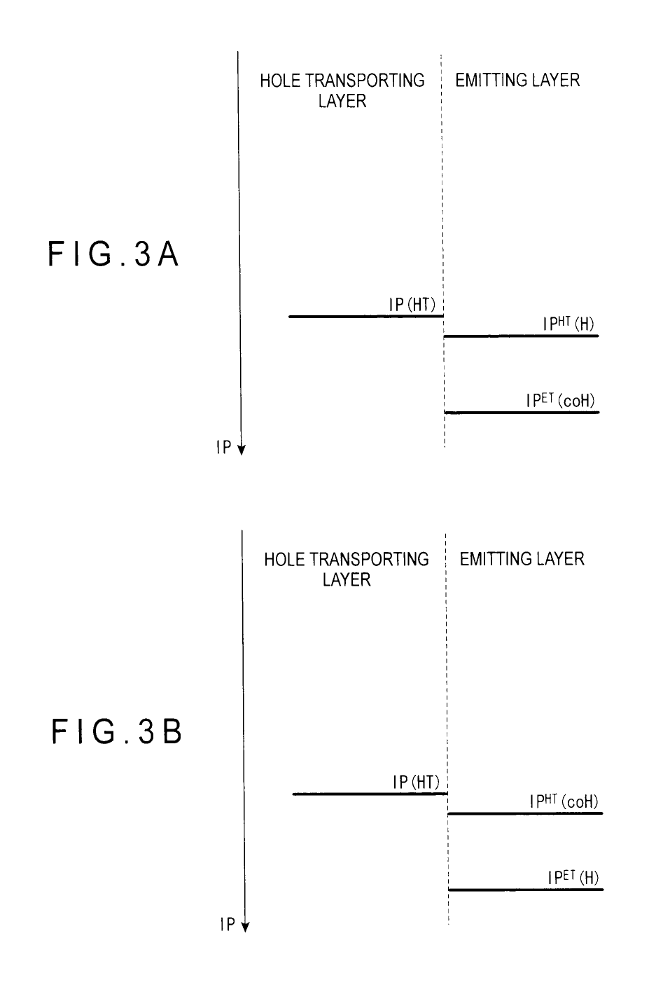

FIGS. 3A and 3B show a combination idea of typical host material and co-host material. In FIGS. 3A and 3B, IP(HT) represents the ionization potential of a hole transporting material, IP^{HT}(H) represents the ionization potential of a hole-transporting host material, IP^{HT}(coH) represents the ionization potential of a hole transporting co-host material, IP^{ET}(H) represents the ionization potential of an electron-transporting host material, and IP^{ET}(coH) represents the ionization potential of an electron transporting co-host material. The typical host material and co-host material correspond to the first host material and second host material according to the exemplary embodiment, respectively. However, the co-host material may be the first host material.

According to the combination idea of typical host material and co-host material, an electron-transporting host material and a hole-transporting host material are combined to improve the carrier balance in the emitting layer. In this case, all of the respective ionization potentials of the host materials and the co-host materials, i.e., IP^{HT}(H), IP^{ET}(H), IP^{HT}(coH) and IP^{ET}(coH), are higher than the ionization potential IP(HT) of the hole transporting material. Holes are injected from the hole transporting layer into the hole-transporting host material or co-host material, which has a small HOMO energy barrier (i.e., a lower ionization potential). The hole-transporting host material or co-host material serves to transport the holes in the emitting layer.

In view of the above, when a large amount of holes are injected from an electrode into an emitting layer or a small amount of electrons are injected from an electrode into an emitting layer in an organic EL device, the carrier balance is unlikely to be improved by adjusting the injected and transported amount of holes.

However, according to the exemplary embodiment, the second host material is added, thereby easily reducing an excessive transported amount of holes.

In particular, when a material having a poor electron injecting capability (e.g., an organic metal complex) is used for forming the electron injecting layer, the carrier balance in the emitting layer becomes shifted toward the cathode to cause a hole excess state. In order to improve the carrier balance, the second host material having a hole trapping property can be selected.

In the exemplary embodiment, the ionization potential IP(h2) of the second host material preferably satisfies the expression (2) and falls within a range from 5.0 eV to 6.0 eV, more preferably 5.3 eV to 5.5 eV.

For instance, when the ionization potential IP(HT) of the hole transporting material falls within a range from 5.5 eV to 5.6 eV, it is preferable that the ionization potential IP(h1) of the first host material falls within a range from 5.7 eV to 5.8 eV and the ionization potential IP(h2) of the second host material falls within a range from 5.3 eV to 5.5 eV.

When the IP(h2) is extremely small relative to the IP(HT), holes are less likely to be trapped by the second host material. When a difference between the IP(HT) and the IP(h1) is extremely increased, the hole transport barrier is increased, so that holes are less likely to be injected.

The ratio of the second host material among the host materials in the emitting layer preferably falls within a range from 10 mass % to 30 mass %. When the ratio of the second host material is within the above range, a favorable carrier balance can be maintained.

The hole mobility of the second host material is preferably higher than the electron mobility thereof. In other words, the second host material preferably exhibits a hole transporting capability.

In the exemplary embodiment, the second host material is preferably represented by the following formula (1).

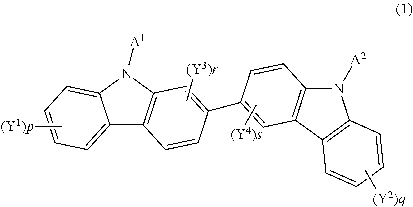

In the formula (1),
A¹ and A² each represent one of the following:

a substituted or unsubstituted aromatic hydrocarbon group having 6 to 30 ring carbon atoms;

a substituted or unsubstituted heterocyclic group having 1 to 30 ring carbon atoms; and

a group represented by the following formula (2).

—X-A³ (2)

X represents a single bond or a linking group.

Examples of the linking group are as follows:

a substituted or unsubstituted aromatic hydrocarbon group having 6 to 30 ring carbon atoms;

a substituted or unsubstituted fused aromatic hydrocarbon group having 6 to 30 ring carbon atoms;

a substituted or unsubstituted aromatic heterocyclic group having 2 to 30 ring carbon atoms; and

a substituted or unsubstituted fused aromatic heterocyclic group having 2 to 30 ring carbon atoms.

A³ represents a substituted or unsubstituted nitrogen-containing heterocyclic group.
Y¹ to Y⁴ each independently represent one of the following:

a hydrogen atom;

a fluorine atom;

a cyano group;

a substituted or unsubstituted alkyl group having 1 to 20 carbon atoms;

a substituted or unsubstituted alkoxy group having 1 to 20 carbon atoms;

a substituted or unsubstituted haloalkyl group having 1 to 20 carbon atoms;

a substituted or unsubstituted haloalkoxy group having 1 to 20 carbon atoms;

a substituted or unsubstituted alkylsilyl group having 1 to 10 carbon atoms;

a substituted or unsubstituted arylsilyl group having 6 to 30 carbon atoms;

a substituted or unsubstituted aromatic hydrocarbon group having 6 to 30 ring carbon atoms;

a substituted or unsubstituted fused aromatic hydrocarbon group having 6 to 30 ring carbon atoms;

a substituted or unsubstituted aromatic heterocyclic group having 2 to 30 ring carbon atoms;

a substituted or unsubstituted fused aromatic heterocyclic group having 2 to 30 ring carbon atoms; and

the group represented by the formula (2).

Adjacent ones of Y¹ to Y⁴ may be bonded to each other to form a ring structure.

Any one of A¹, A² and Y¹ to Y⁴ contains the group represented by the formula (2).

p and q each represent an integer of 1 to 4 and r and s each represent an integer of 1 to 3.

When each of p and q is an integer of 2 to 4 and each of r and s is an integer of 2 to 3, a plurality of Y¹ to Y⁴ may be the same or different.

In the formula (1), the groups represented by Y¹ to Y⁴, i.e., the alkyl group, alkoxy group, haloalkyl group, haloalkoxy group and alkylsilyl group, may be linear, branched or cyclic.

In the formula (1), examples of the alkyl group having 1 to 20 carbon atoms are a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, n n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neo-pentyl group, a 1-methylpentyl group, a 2-methylpentyl group, a 1-pentylhexyl group, a 1-butylpentyl group, a 1-heptyloctyl group, a 3-methylpentyl group, a cyclopentyl group, a cyclohexyl group, a cyclooctyl group and a 3,5-tetramethylcyclohexyl group.

As the alkoxy group having 1 to 20 carbon atoms, an alkoxy group having 1 to 6 carbon atoms is preferable and specific examples thereof are a methoxy group, an ethoxy group, a propoxy group, butoxy group, pentyloxy group and hexyloxy group.

The haloalkyl group having 1 to 20 carbon atoms is exemplified by a haloalkyl group provided by substituting the alkyl group having 1 to 20 carbon atoms with one or more halogen groups.

The haloalkoxy group having 1 to 20 carbon atoms is exemplified by a haloalkoxy group provided by substituting the alkoxy group having 1 to 20 carbon atoms with one or more halogen groups.

Examples of the alkylsilyl group having 1 to 10 carbon atoms are a trimethylsilyl group, a triethylsilyl group, a tributylsilyl group, a dimethylethylsilyl group, a dimethylisopropylsilyl group, a dimethylpropylsilyl group, a dimethylbutylsilyl group, a dimethyl-tertiary-butylsilyl group and a diethylisopropylsilyl group.

Examples of the arylsilyl group having 6 to 30 carbon atoms are a phenyldimethylsilyl group, a diphenylmethylsilyl group, a diphenyl-tertiary-butylsilyl group and a triphenylsilyl group.

Examples of the aromatic heterocyclic group or fused aromatic heterocyclic group having 2 to 30 ring carbon atoms are a pyroryl group, a pyrazinyl group, a pyridinyl group, an indolyl group, an isoindolyl group, a furyl group, a benzofuranyl group, an isobenzofuranyl group, a dibenzofuranyl group, a dibenzothiophenyl group, a quinolyl group, an isoquinolyl group, a quinoxalinyl group, a carbazolyl group, a phenantridinyl group, an acridinyl group, a phenanthrolinyl group, a thienyl group, and a group formed from a pyridine ring, a pyrazine ring, a pyrimidine ring, a pyridazine ring, a triazine ring, an indol ring, a quinoline ring, an acridine ring, a pirrolidine ring, a dioxane ring, a piperidine ring, a morpholine ring, a piperadine ring, a carbazole ring, a furan ring, a thiophene ring, an oxazole ring, an oxadiazole ring, a benzooxazole ring, a thiazole ring, a thiadiazole ring, a benzothiazole ring, a triazole ring, an imidazole ring, a benzoimidazole ring, a pyrane ring and a dibenzofuran ring.

Examples of the aromatic hydrocarbon group or fused aromatic hydrocarbon group having 6 to 30 ring carbon atoms are a phenyl group, a naphthyl group, a phenanthryl group, a biphenyl group, a terphenyl group, a quarterphenyl group, a fluoranthenyl group, a triphenylenyl group and a phenanthrenyl group.

When A¹, A², A³, X and Y¹ to Y⁴ of the formula (1) each have one or more substituents, the substituents are preferably a linear, branched or cyclic alkyl group having 1 to 20 carbon atoms; linear, branched or cyclic alkoxy group having 1 to 20 carbon atoms; linear, branched or cyclic haloalkyl group having 1 to 20 carbon atoms; linear, branched or cyclic alkylsilyl group having 1 to 10 carbon atoms; arylsilyl group having 6 to 30 ring carbon atoms; cyano group; halogen atom; aromatic hydrocarbon group or fused aromatic hydrocarbon group having 6 to 30 ring carbon atoms; or aromatic heterocyclic group or fused aromatic heterocyclic group having 2 to 30 ring carbon atoms.

Examples of the linear, branched or cyclic alkyl group having 1 to 20 carbon atoms; linear, branched or cyclic alkoxy group having 1 to 20 carbon atoms; linear, branched or cyclic haloalkyl group having 1 to 20 carbon atoms; linear, branched or cyclic alkylsilyl group having 1 to 10 carbon atoms; arylsilyl group having 6 to 30 ring carbon atoms; aromatic hydrocarbon group or fused aromatic hydrocarbon group having 6 to 30 ring carbon atoms; and aromatic heterocyclic group or fused aromatic heterocyclic group having 2 to 30 ring carbon atoms are the above-described groups. The halogen atom is exemplified by a fluorine atom.

Examples of the substituted or unsubstituted nitrogen-containing heterocyclic group represented by A³ of the formula (2) are nitrogen-containing ones of the aromatic heterocyclic group(s) or fused aromatic heterocyclic group(s) having 2 to 30 ring carbon atoms.

For the compound represented by the formula (1), at least one of A¹ and A² is preferably the group represented by the formula (2). Further, for the compound represented by the formula (1), X of the formula (2) is preferably a single bond. For the compound represented by the formula (1), A¹ is particularly preferably the group represented by the formula (2) and X of the formula (2) is preferably a single bond. In other words, the compound is preferably represented by the following formula (1-1).

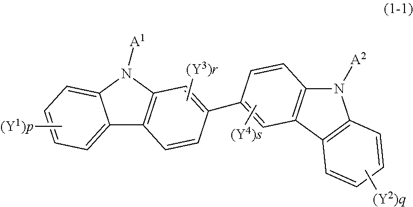

Examples of the compound represented by the formula (1) or the formula (1-1) are shown below.

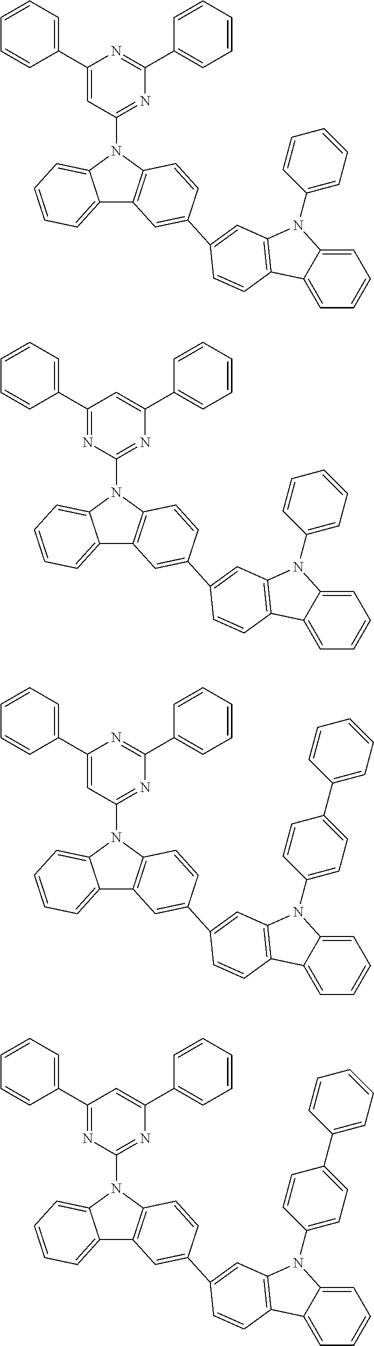

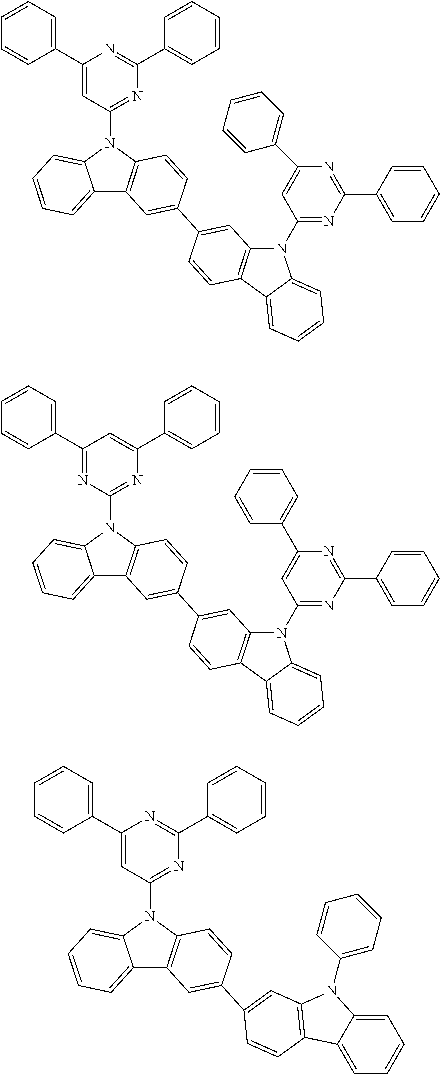

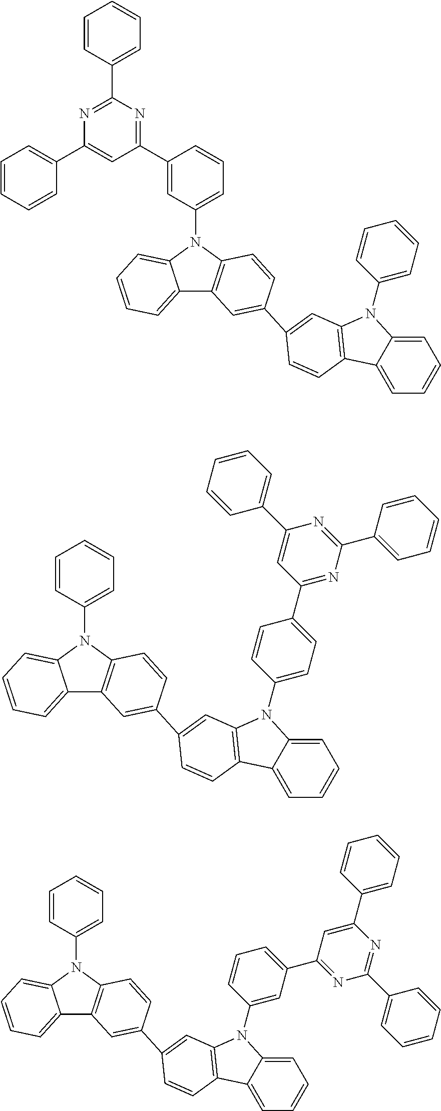

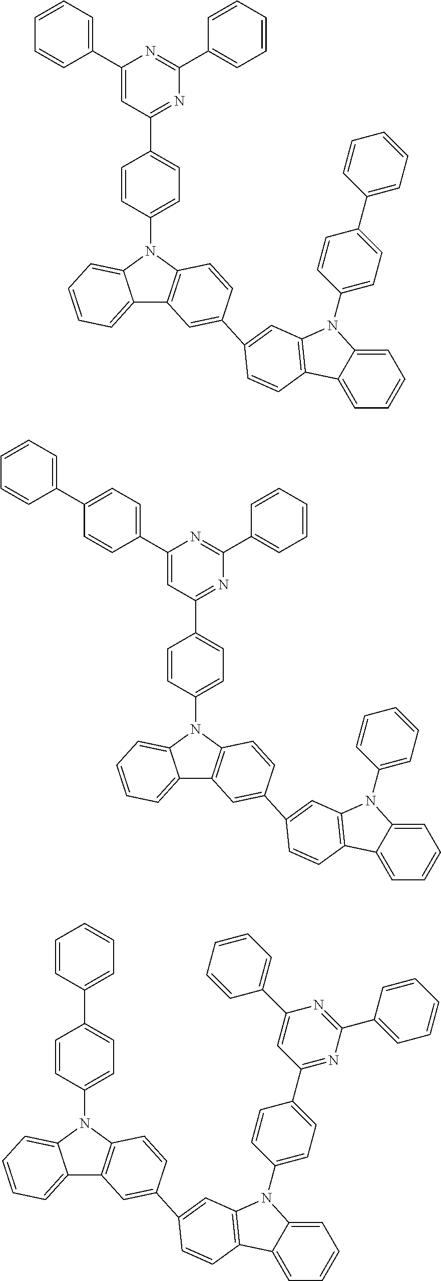

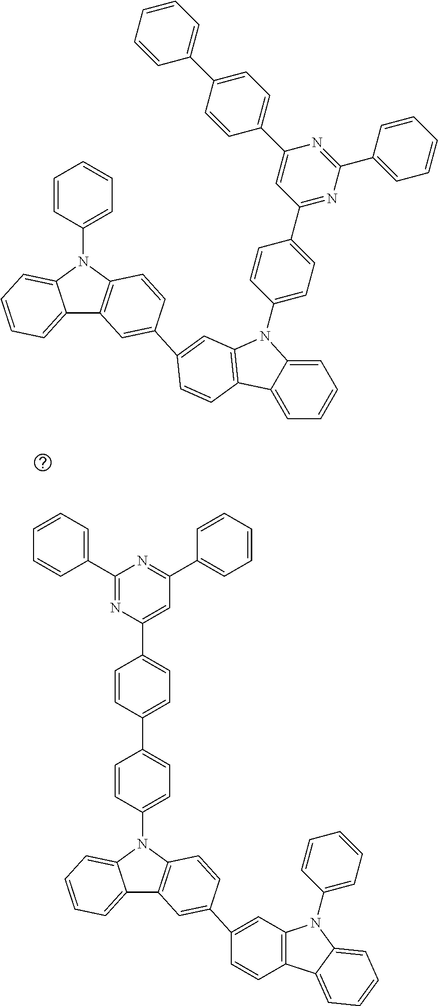

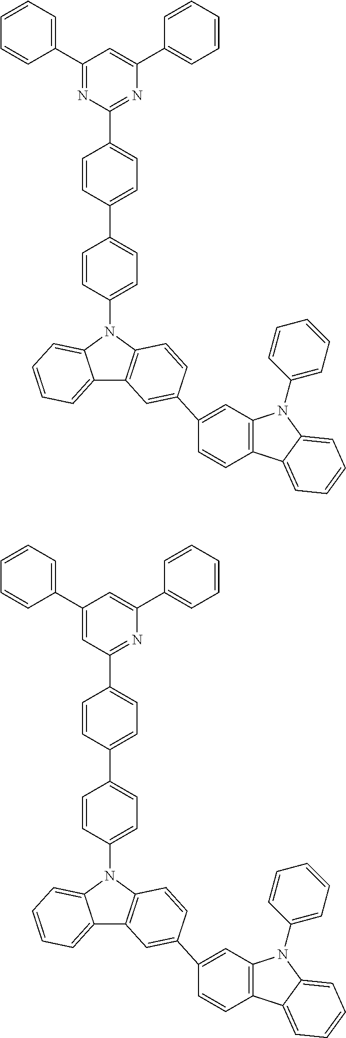

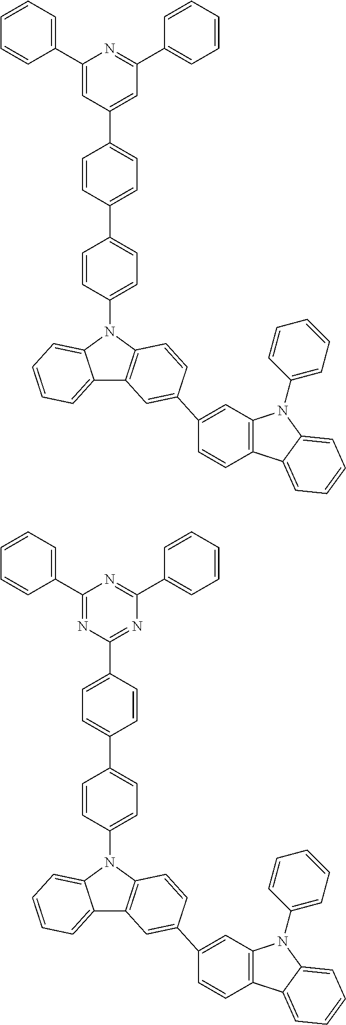

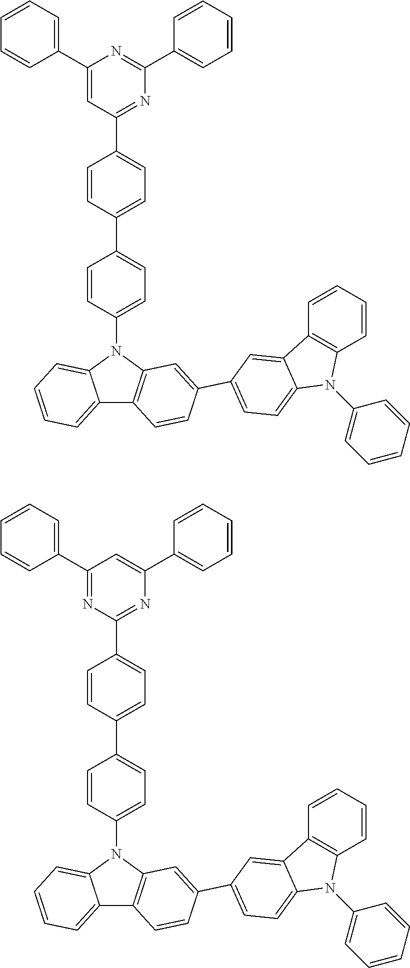

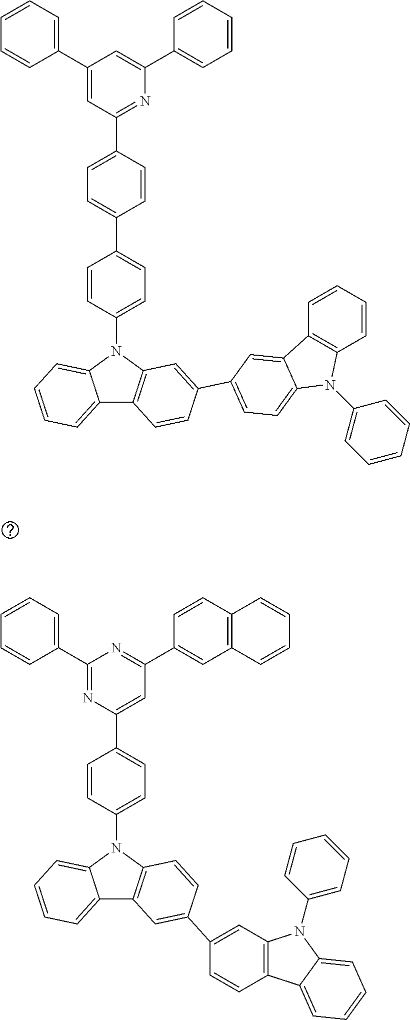

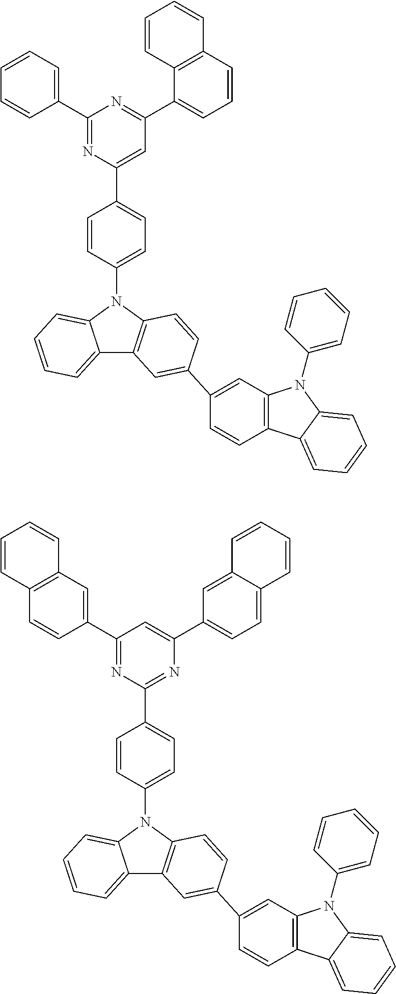

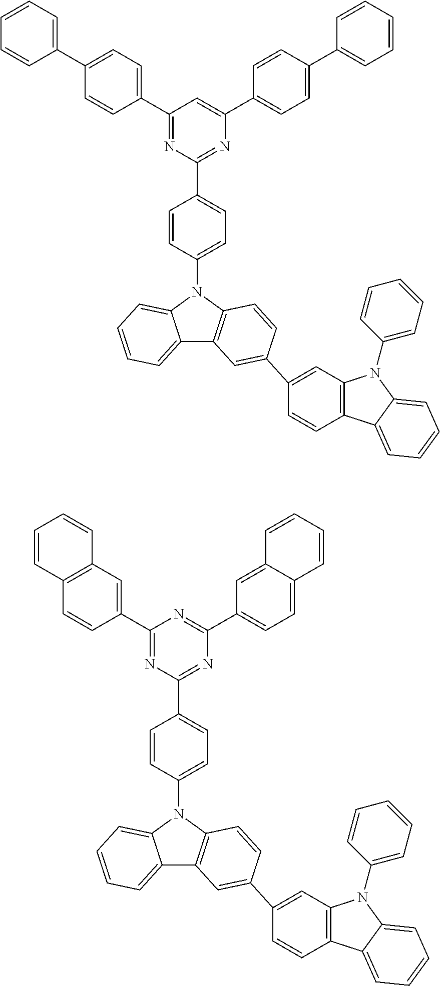

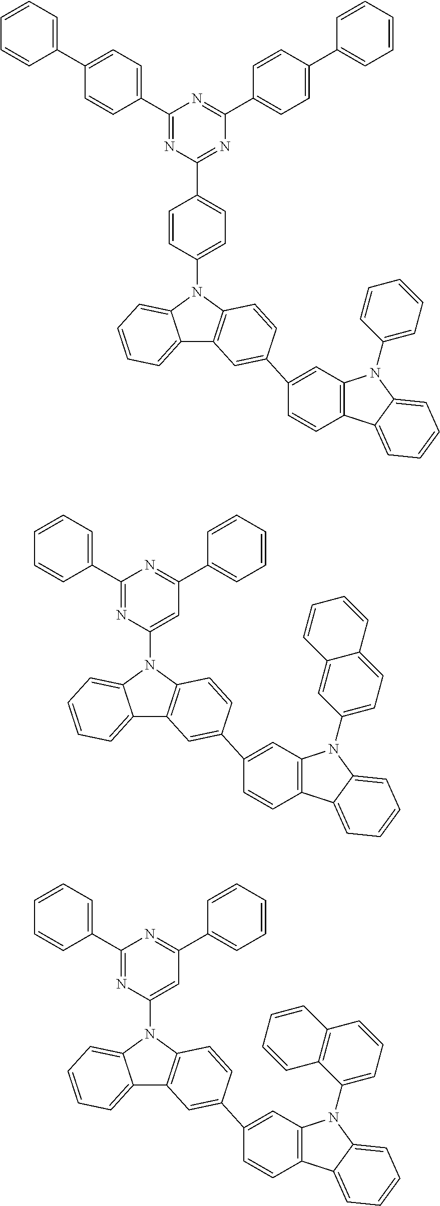

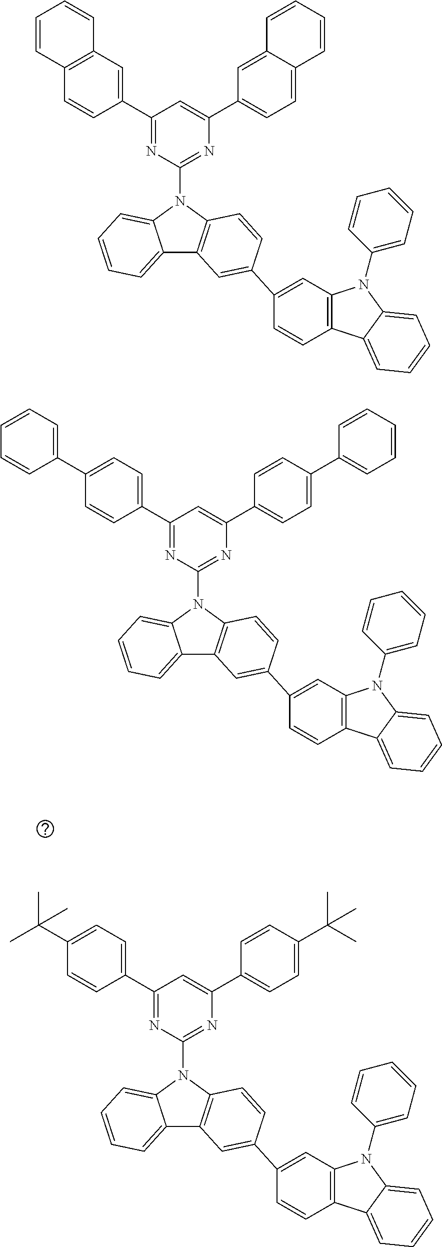

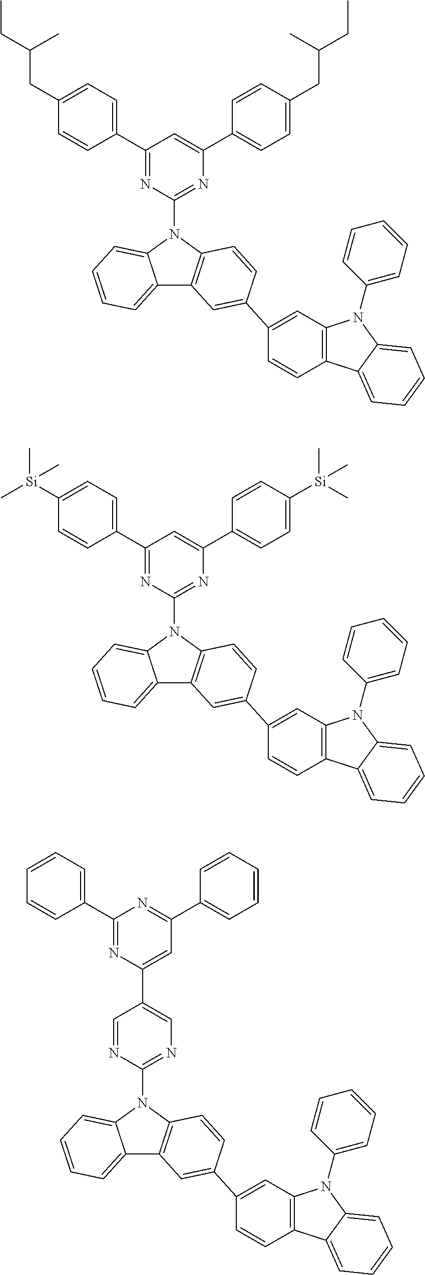

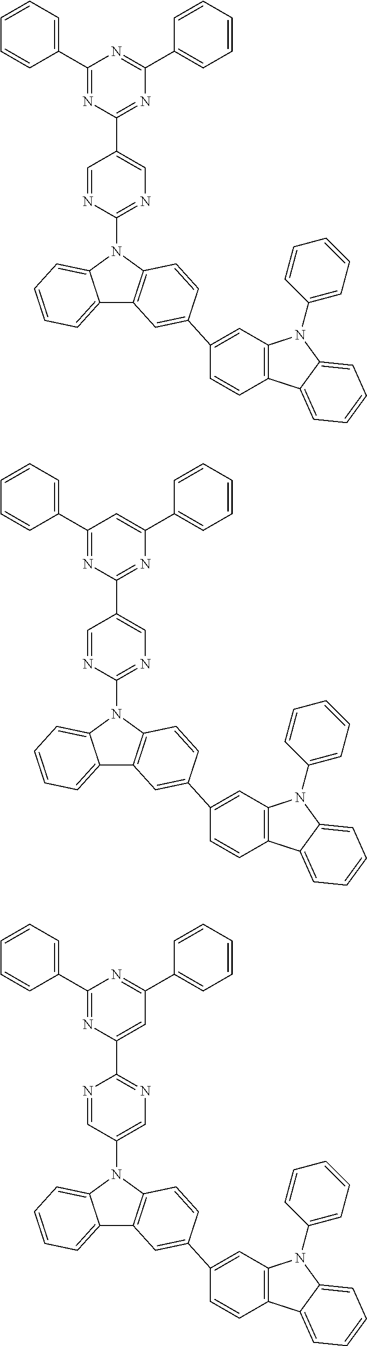

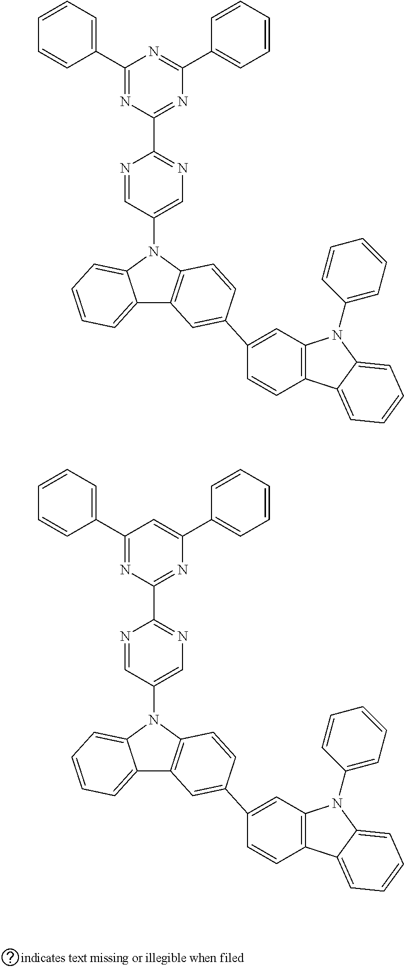

Among the above exemplary compounds, the following compound is particularly preferably usable as a compound that satisfies the relationship in ionization potential represented by the expression (2) to improve the carrier balance in the emitting layer.

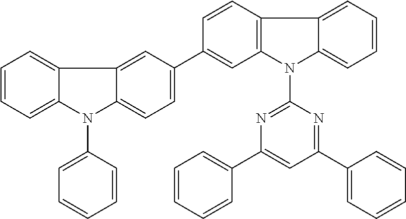

### First Host Material

As the first host material usable in the organic EL device according to the exemplary embodiment, a compound excellent in hole transporting capability and a bipolar compound capable of transporting holes and electrons are preferably usable.

The first host material is subject to no specific limitation and typical host materials such as an amine derivative, azine derivative and fused polycyclic aromatic derivative are usable as the first host material.

Examples of the amine derivative are a monoamine compound, a diamine compound, a triamine compound, a tetramine compound, and an amine compound substituted with a carbazole group.

Examples of the azine derivative are a monoazine derivative, a diazine derivative and a triazine derivative.

The fused polycyclic aromatic derivative is preferably a fused polycyclic aromatic hydrocarbon having no heterocyclic skeleton. Examples of the fused polycyclic aromatic derivative are the fused polycyclic aromatic hydrocarbon such as naphthalene, anthracene, phenanthrene, chrysene, fluoranthene and triphenylene, or derivatives thereof.

Specific examples of the first host material are a carbazole derivative; a triazoles derivative; an oxazole derivative; an oxadiazole derivative; an imidazole derivative; a polyarylalkane derivative; a pyrazoline derivative; a pyrazolone derivative; a phenylenediamine derivative; an arylamine derivative; an amino-substituted chalcone derivative; a styryl anthracene derivative; a fluorenone derivative; a hydrazone derivative; a stilbene derivative; a silazane derivative; an aromatic tertiary amine compound; a styrylamine compound; an aromatic dimethylidene compound; a porphyrin compound; an anthraquinodimethane derivative; an anthrone derivative; a diphenylquinone derivative; a thiopyrandioxide derivative; a carbodiimide derivative; a fluorenylidenemethan derivative; a distyryl pyrazine derivative; a hyterocyclic tetracarboxylic acid anhydride such as naphthaleneperylene; a phthalocyanine derivative; various metal complex polysilane compounds typified by a metal complex of 8-quinolinol derivative and a metal complex having metal phthalocyanine, benzoxazole or benzothiazole as the ligand; a poly(N-vinylcarbazole) derivative; an aniline copolymer; conductive high molecular weight oligomers such as thiophene oligomer and polythiophene, polymer compounds such as polythiophene derivative; a polyphenylene derivative; a polyphenylene vinylene derivative; and a polyfluorene derivative.

Further specifically, the first host material is exemplified by a compound represented by the following formula (3).

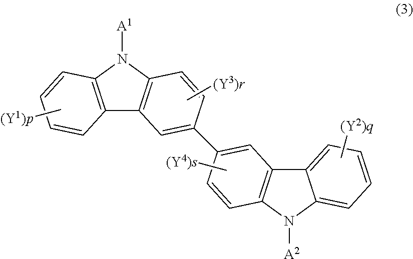

In the formula (3), A¹, A², Y¹ to Y⁴, p, q, r and s represent the same as those of the formula (1), respectively.

Further, in the compound represented by the formula (3) for the first host material, it is preferable that:

at least one of A¹ and A² is the group represented by the formula (2); and

X of the formula (2) represents one of the following:

a substituted or unsubstituted aromatic hydrocarbon group having 6 to 30 ring carbon atoms;

a substituted or unsubstituted fused aromatic hydrocarbon group having 6 to 30 ring carbon atoms;

a substituted or unsubstituted aromatic heterocyclic group having 2 to 30 ring carbon atoms; and

a substituted or unsubstituted fused aromatic heterocyclic group having 2 to 30 ring carbon atoms.

The first host material may preferably be a compound represented by the following formula (4).

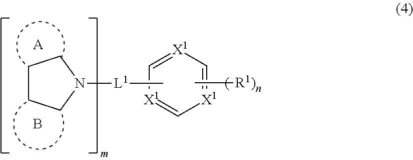

In the formula (4), A and B each represent a six-membered ring. The six-membered ring represented by each of A and B may be further fused with another ring.

L¹ of the formula (4) represents a single bond or a linking group and examples of the linking group are as follows:

a substituted or unsubstituted aryl group having 6 to 30 ring carbon atoms;

a substituted or unsubstituted heterocyclic group having 5 to 30 ring carbon atoms;

a cycloalkyl group having 5 to 30 ring carbon atoms; and

a group provided by mutually bonding the above groups.

X¹ is a nitrogen atom or C—R¹⁰ and at least one of plural X¹ is a nitrogen atom.

R¹ and R¹⁰ each independently represent one of the following:

a hydrogen atom;

a deuterium atom;

a halogen atom;

a cyano group;

a substituted or unsubstituted aryl group having 6 to 30 ring carbon atoms;

a substituted or unsubstituted heterocyclic group having 5 to 30 ring carbon atoms;

a substituted or unsubstituted alkyl group having 1 to 30 carbon atoms;

a substituted or unsubstituted alkenyl group having 2 to 30 carbon atoms;

a substituted or unsubstituted alkynyl group having 2 to 30 carbon atoms;

a substituted or unsubstituted alkylsilyl group having 3 to 30 carbon atoms;

a substituted or unsubstituted arylsilyl group having 6 to 30 ring carbon atoms;

a substituted or unsubstituted alkoxy group having 1 to 30 carbon atoms;

a substituted or unsubstituted aralkyl group having 6 to 30 ring carbon atoms; and

a substituted or unsubstituted aryloxy group having 6 to 30 ring carbon atoms.

Plural R¹ may be mutually the same or different.
Plural R¹⁰ may be mutually the same or different.

m and n each represent an integer of 1 to 2.

The compound of the formula (4) is preferably represented by one of the following formulae (5-A) to (5-G).

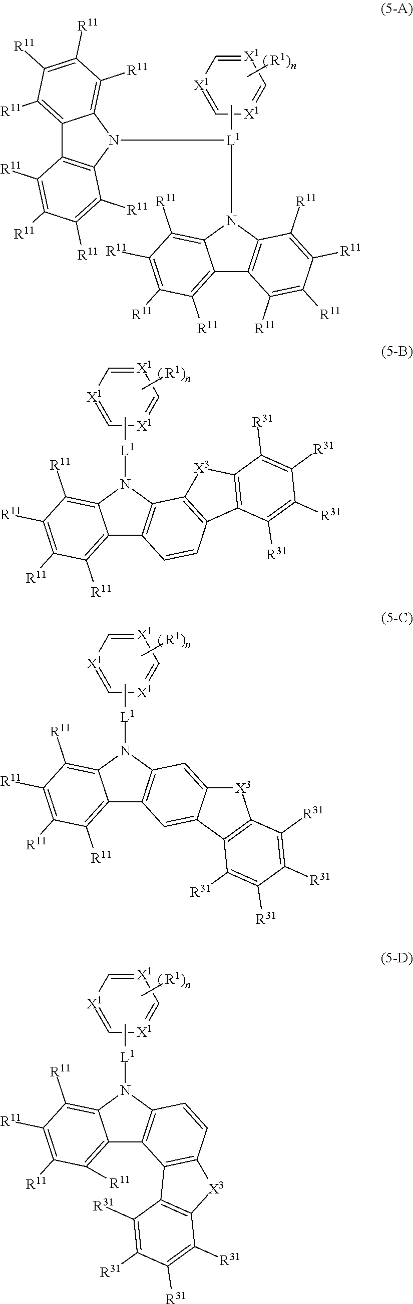

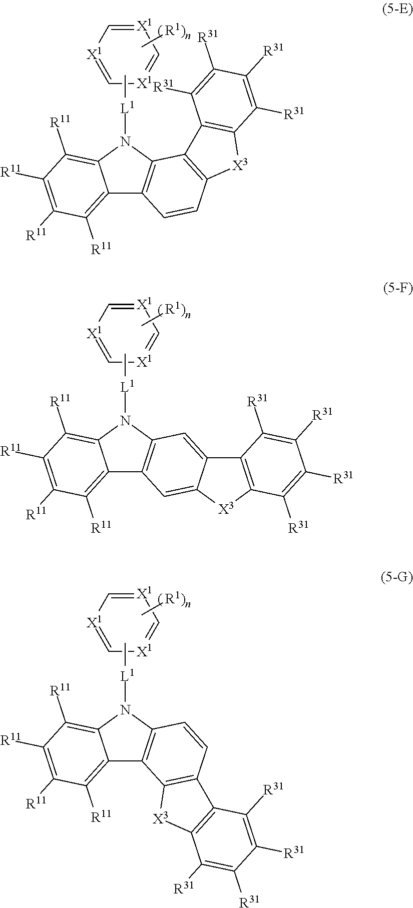

In the formulae (5-A) to (5-G), L¹, X¹, R¹, n and m represent the same as those of the formula (4), respectively.

R¹¹ and R¹³ represent the same as those of the formula (4), respectively.

X³ represents an oxygen atom or N—R³².

R³² represents the same as R¹ of the formula (4).

Although depending on a combination of the hole transporting material and the second host material, the ionization potential IP(h1) of the first host material preferably falls within a range from 5.3 eV to 6.3 eV, more preferably from 5.6 eV to 6.3 eV.

### Phosphorescent Dopant Material

In the exemplary embodiment, the phosphorescent dopant material contains a metal complex. The metal complex preferably has a metal atom selected from Ir (iridium), Pt (platinum), Os (osmium), Au (gold), Cu (copper), Re (rhenium) and Ru (ruthenium), and a ligand. Particularly, the ligand preferably has an ortho-metal bond.

The phosphorescent dopant material is preferably a compound containing a metal atom selected from Ir, Os and Pt because such a compound, which exhibits a high phosphorescence quantum yield, can further enhance the external quantum efficiency of an organic EL device. The phosphorescent dopant material is further preferably one of metal complexes such as an iridium complex, osmium complex and platinum complex, among which an iridium complex and platinum complex are more preferable and ortho metalation of an iridium complex is the most preferable.

Examples of the preferable metal complexes are shown below.

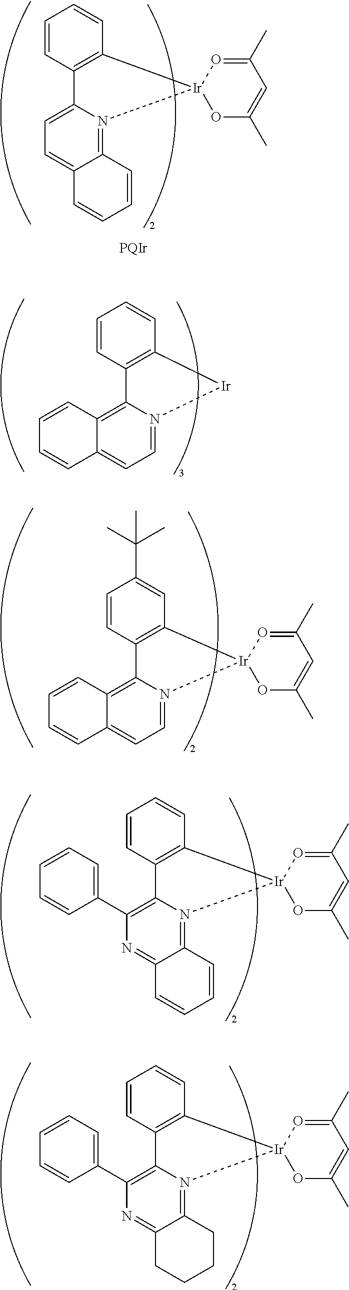

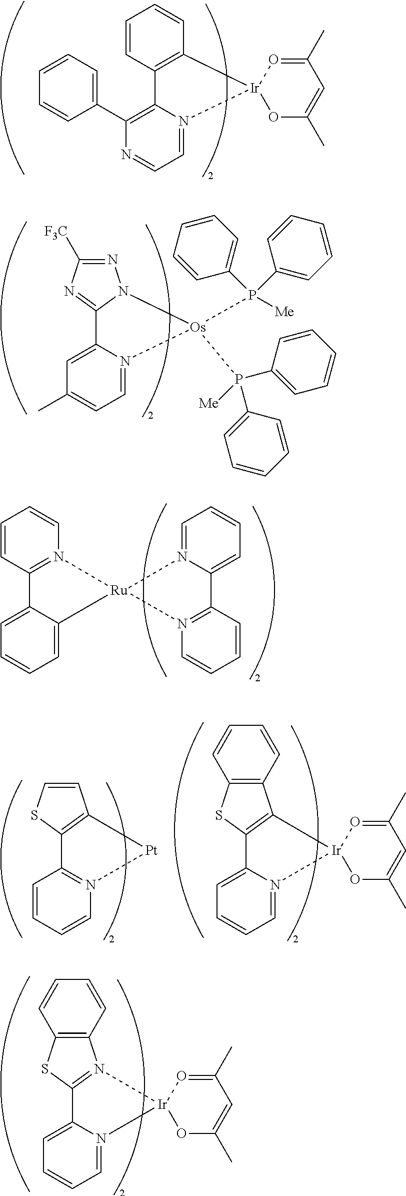

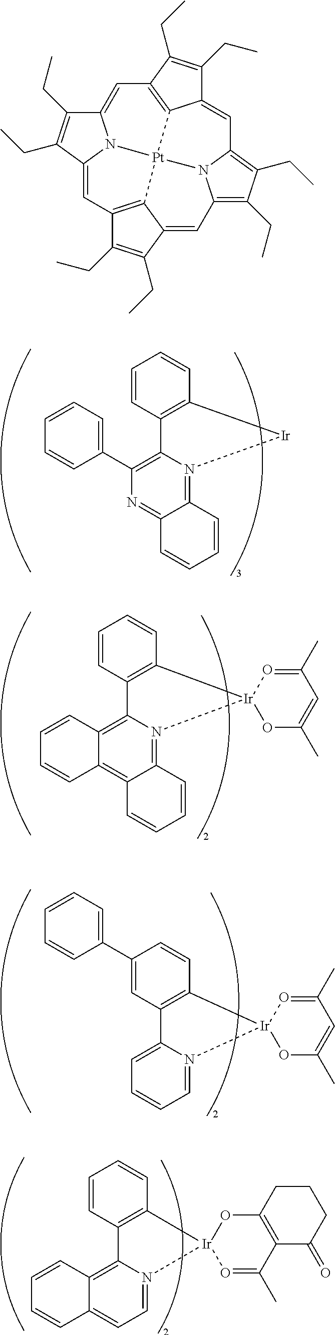

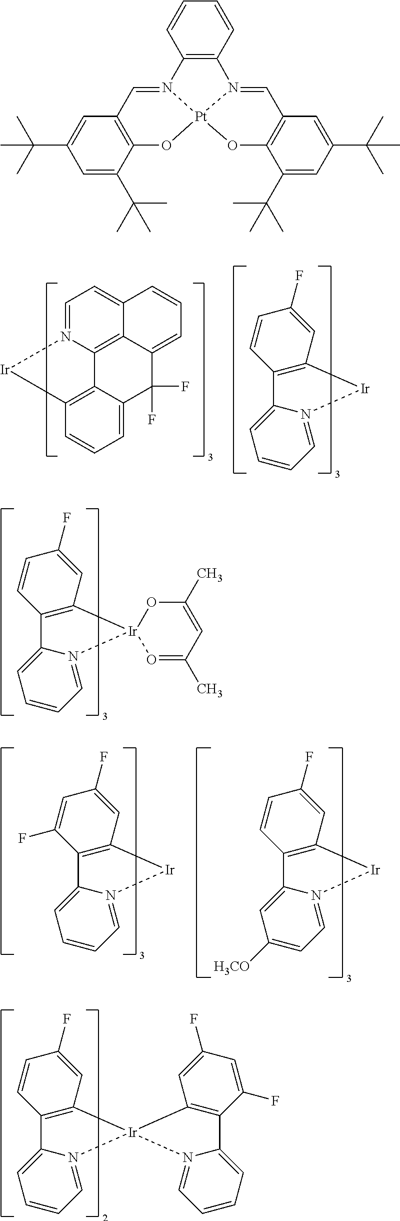

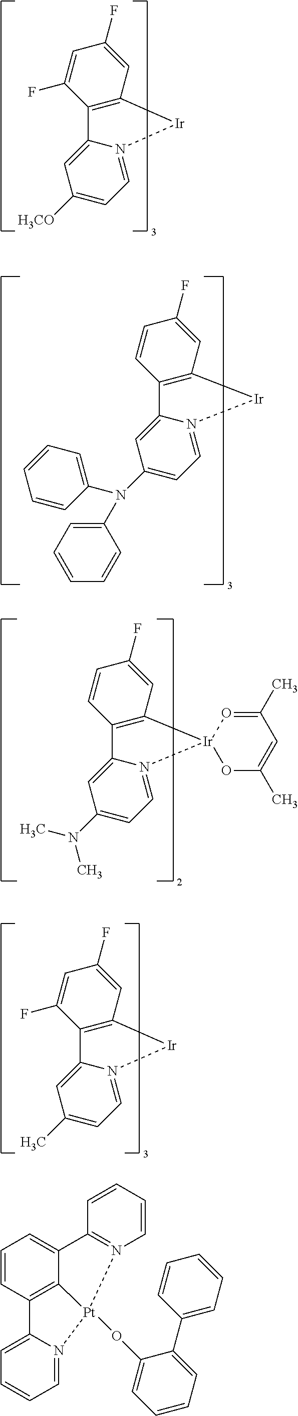

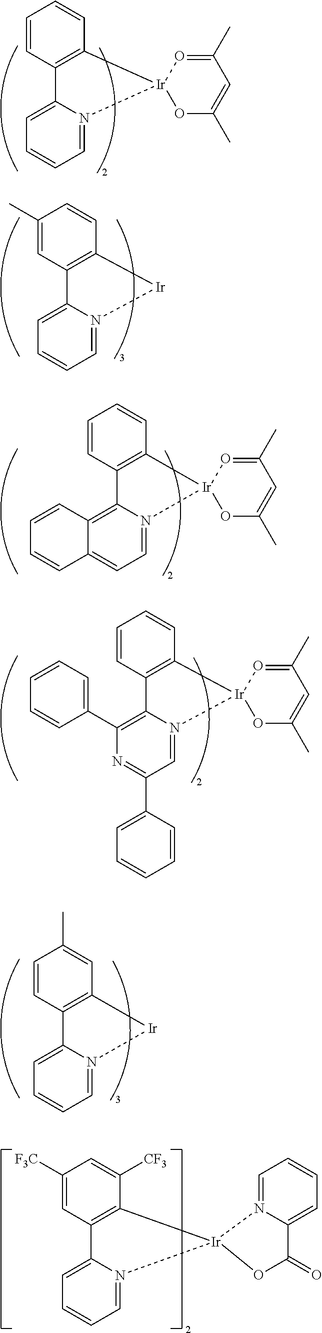

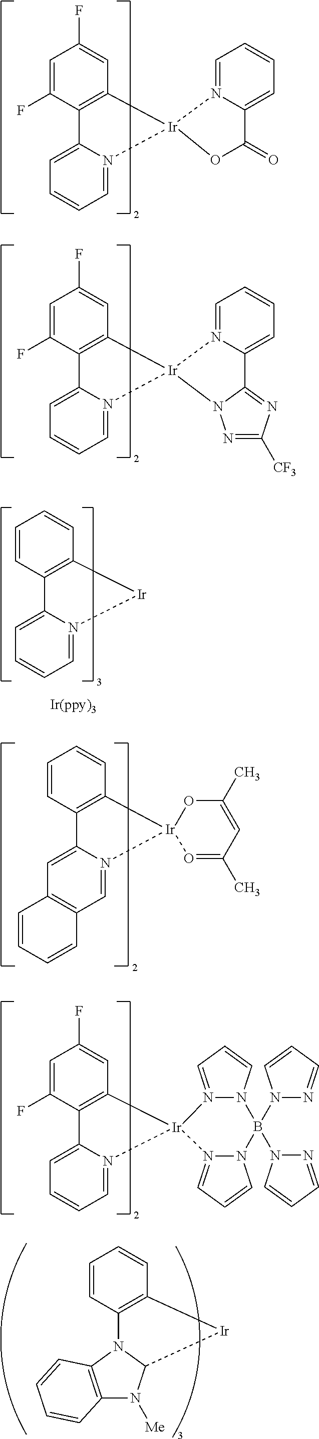

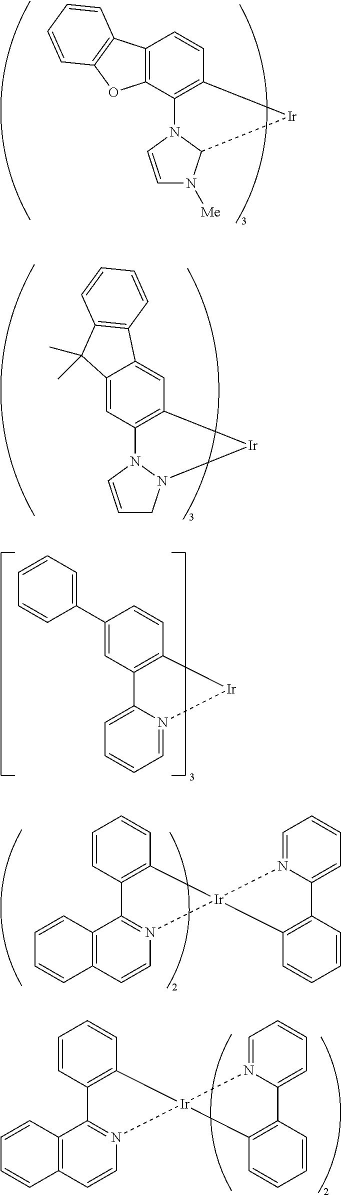

In the exemplary embodiment, at least one phosphorescent dopant material contained in the emitting layer preferably emits light having a maximum wavelength of 420 to 720 nm, more preferably light having a maximum wavelength of 480 nm to 570 nm.

By doping the phosphorescent dopant material having such an emission wavelength to a specific host material usable for the exemplary embodiment so as to form the emitting layer, the organic EL device can exhibit a high efficiency.

### Electron Transporting Layer

The electron transporting layer 7, which aids injection of the electrons into the emitting layer, has a high electron mobility.

In the exemplary embodiment, the electron transporting layer is preferably provided between the emitting layer and the cathode, and may preferably contain a nitrogen-containing cyclic derivative as the main component.

It should be noted that “as the main component” means that the nitrogen-containing cyclic derivative is contained in the electron transporting layer at a content of 50 mass % or more.

A preferred example of an electron transporting material for forming the electron transporting layer is an aromatic heterocyclic compound having in the molecule at least one heteroatom. Particularly, a nitrogen-containing cyclic derivative is preferable. The nitrogen-containing cyclic derivative is preferably an aromatic ring having a nitrogen-containing six-membered or five-membered ring skeleton, or a fused aromatic cyclic compound having a nitrogen-containing six-membered or five-membered ring skeleton.

A preferred example of the nitrogen-containing cyclic derivative is a nitrogen-containing cyclic metal chelate complex represented by the following formula (B1).

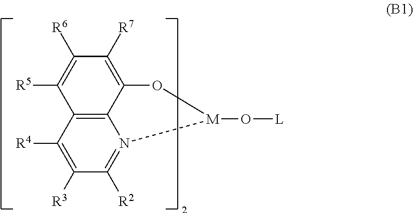

R² to R⁷ of the formula (B1) independently represent one of the following:

a hydrogen atom;

a halogen atom;

an oxy group;

an amino group;

a hydrocarbon group having 1 to 40 carbon atoms;

an alkoxyl group;

an aryloxy group;

an alkoxycarbonyl group; and

an aromatic heterocyclic group.

The above groups may be substituted.

Examples of the halogen atom are fluorine, chlorine, bromine and iodine. In addition, examples of the substituted or unsubstituted amino group are an alkylamino group, an arylamino group and an aralkylamino group.

The alkoxycarbonyl group is represented by —COOY'. Examples of Y′ are the same as the examples for the alkyl group. The alkylamino group and the aralkylamino group are represented by —NQ¹Q². Examples for each of Q¹ and Q² are the same as those mentioned in relation to the alkyl group and the aralkyl group (i.e., a group provided by substituting a hydrogen atom in the alkyl group with an aryl group), and preferred examples for each of Q¹ and Q² are also the same as those mentioned in relation to the alkyl group and the aralkyl group. Either one of Q¹ and Q² may be a hydrogen atom.

The arylamino group is represented by —NAr¹Ar². Examples for each of Ar¹ and Ar² are the same as the groups mentioned in relation to the aromatic hydrocarbon group and the fused aromatic hydrocarbon group. Either one of Ar¹ and Ar² may be a hydrogen atom.

M represents one of aluminum (Al), gallium (Ga) and indium (In), among which In is preferable.

L of the formula (B1) represents a substituted or unsubstituted phenyl group or a substituted or unsubstituted triphenylsilyl group.

The electron transporting layer preferably contains at least one of nitrogen-containing heterocycle derivatives respectively represented by the following formulae (B2) to (B4).

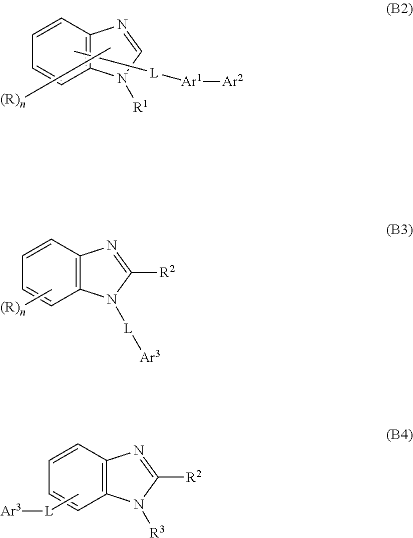

R of the formulae (B2) to (B4) represents one of the following:

a hydrogen atom;

an aromatic hydrocarbon group having 6 to 60 ring carbon atoms;

a fused aromatic hydrocarbon group having 6 to 60 ring carbon atoms;

a pyridyl group;

a quinolyl group;

an alkyl group having 1 to 20 carbon atoms; and

an alkoxy group having 1 to 20 carbon atoms.

n is an integer of 0 to 4.

R¹ of the formulae (B2) to (B4) represents one of the following:

an aromatic hydrocarbon group having 6 to 60 ring carbon atoms;

a fused aromatic hydrocarbon group having 6 to 60 ring carbon atoms;

a pyridyl group;

a quinolyl group;

an alkyl group having 1 to 20 carbon atoms; and

an alkoxy group having 1 to 20 carbon atoms.

R² and R³ of the formulae (B2) to (B4) each independently represent one of the following:

a hydrogen atom;

an aromatic hydrocarbon group having 6 to 60 ring carbon atoms;

a fused aromatic hydrocarbon group having 6 to 60 ring carbon atoms;

a pyridyl group;

a quinolyl group;

an alkyl group having 1 to 20 carbon atoms; and

an alkoxy group having 1 to 20 carbon atoms.

L of the formulae (B2) to (B4) represents one of the following:

an aromatic hydrocarbon group having 6 to 60 ring carbon atoms;

a fused aromatic hydrocarbon group having 6 to 60 ring carbon atoms;

a pyridinylene group;

a quinolinylene group; and

a fluorenylene group.

Ar¹ of the formulae (B2) to (B4) represents one of the following:

an aromatic hydrocarbon group having 6 to 60 ring carbon atoms;

a fused aromatic hydrocarbon group having 6 to 60 ring carbon atoms;

a pyridinylene group; and

a quinolinylene group.

Ar² of the formulae (B2) to (B4) represents one of the following:

an aromatic hydrocarbon group having 6 to 60 ring carbon atoms;

a fused aromatic hydrocarbon group having 6 to 60 ring carbon atoms;

a pyridyl group;

a quinolyl group;

an alkyl group having 1 to 20 carbon atoms; and

an alkoxy group having 1 to 20 carbon atoms.

Ar³ of the formulae (B2) to (B4) represents one of the following:

an aromatic hydrocarbon group having 6 to 60 ring carbon atoms;

a fused aromatic hydrocarbon group having 6 to 60 ring carbon atoms;

a pyridyl group;

a quinolyl group;

an alkyl group having 1 to 20 carbon atoms;

an alkoxy group having 1 to 20 carbon atoms; and

a group represented by -Ar¹-Ar² (each of Ar¹ and Ar² is the same as described above).

The aromatic hydrocarbon group, fused aromatic hydrocarbon group, pyridyl group, quinolyl group, alkyl group, alkoxy group, pyridinylene group, quinolinylene group and fluorenylene group mentioned above in relation to R, R¹, R², R³, L, Ar¹, Ar² and Ar³ of the formulae (B2) to (B4) may be substituted.

### Electron Injecting Layer

The electron injecting layer 8 is provided for adjusting energy level, by which, for instance, sudden changes of the energy level can be reduced.

In the exemplary embodiment, it is preferable that the electron injecting layer is provided between the cathode and the anode and is adjacent to the cathode. The electron injecting layer preferably contains an organic metal complex.

The organic metal complex contained in the electron injecting layer is preferably an organic metal complex containing an alkali metal, and is preferably exemplified by a compound represented by any one of the following formulae (10) to (12).

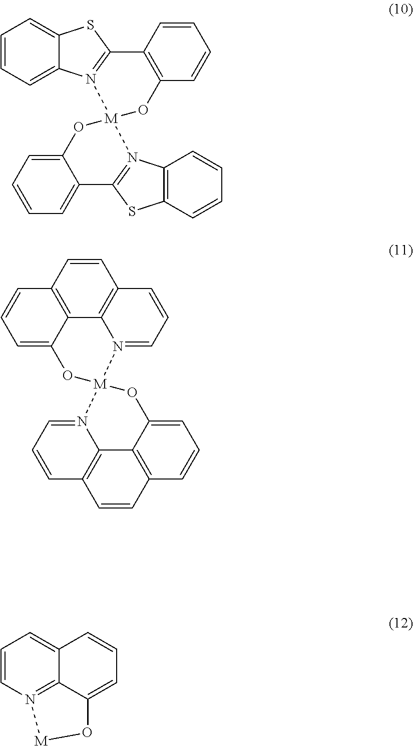

In the formulae (10) to (12), M represents an alkali metal atom.

Examples of the alkali metal are Li (lithium), Na (sodium), K (potassium), Rb (rubidium) and Cs (cesium).

Among the above, the alkali metal is preferably a lithium complex, particularly preferably an 8-quinolinolato lithium (Liq).

The thickness of the electron injecting layer 8 preferably falls within a range from 0.5 nm to 3 nm. When the thickness of the electron injecting layer 8 falls within the above range, driving voltage is favorably lowered.

A method of forming each layer of the organic EL device according to the exemplary embodiment is subject to no specific limitation, but a typical method may be usable.

Examples of the method of forming each layer are vacuum deposition, molecular beam epitaxy (MBE method), and methods using a solution prepared by dissolving a material in a solvent, such as dipping, spin coating, bar coating, roll coating and LB method.

When each layer is formed by vacuum deposition, each layer can be formed as a thin film. Each thin film may be formed by subsequently depositing molecules of a material. Specific examples of the thus formed thin film are a thin film formed by depositing a material in gas phase and a thin film formed by solidifying a material in a solution state or in liquid phase.

Such a thin film is generally distinguished from a thin film formed by the LB method (a molecular accumulation film) by differences in aggregation structure, higher order structure, and functional differences arising therefrom. For forming each layer by spin coating, a method disclosed in JP-A-57-51781 is employable. Specifically, a solution prepared by dissolving a binder (e.g., a resin) and a material in a solvent is used to form each layer.

Modifications

Although the hole transporting layer is formed continuously with the anode in the exemplary embodiment, a hole injecting layer may be further provided between the anode and the hole transporting layer. Although the electron transporting layer is formed continuously with the cathode in the exemplary embodiment, an electron injecting layer may be further provided between the cathode and the electron transporting layer.

In the organic EL device according to the exemplary embodiment, a reduction-causing dopant may be contained in an interfacial region between the cathode and the electron transporting layer. The organic EL device can thus emit light with an enhanced luminance intensity and have a longer lifetime. The reduction-causing dopant may be at least one compound selected from an alkali metal, an alkali metal complex, an alkali metal compound, an alkaline earth metal, an alkaline earth metal complex, an alkaline earth metal compound, a rare-earth metal, a rare-earth metal complex, a rare-earth metal compound and the like.

### EXAMPLES

Next, the invention will be described in further detail with reference to Example(s) and Comparative(s). However, the invention is not limited by the description of Example(s).

### Example 1

An organic EL device according to Example 1 was manufactured as follows.

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes.

After the glass substrate having the transparent electrode line was cleaned, the glass substrate was mounted on a substrate holder of a vacuum deposition apparatus. A compound HI-1 was deposited to form a 30-nm thick HI-1 film on a surface of the glass substrate where the transparent electrode line was provided so as to cover the transparent electrode. The HI-1 film serves as a hole injecting layer.

A compound HT-1 was deposited on the HI-1 film to form a 100-nm thick HT-1 film. The HT-1 film serves as a first hole transporting layer.

Next, a compound HT-2 was deposited on the HT-1 film to form a 70-nm thick HT-2 film. The HT-2 film serves as a second hole transporting layer.

PG-1 (the first host material), PG-2 (the second host material) and Ir(ppy)₃ (the phosphorescent dopant material) were co-deposited on the second hole transporting layer. Thus, a 40-nm thick emitting layer of green emission was formed. The concentration of each of the dopant material and the second host material was 10 mass %.

A compound ET-1 and Liq were co-deposited on the emitting layer to form a 25-nm thick electron transporting layer. The concentration of the ET-1 was 50 mass %.

Liq was deposited on the electron transporting layer at a rate of 1 Å/min to form a 1-nm thick electron injecting layer. A metal Al was further deposited on the electron injecting layer to form an 80-nm thick cathode.

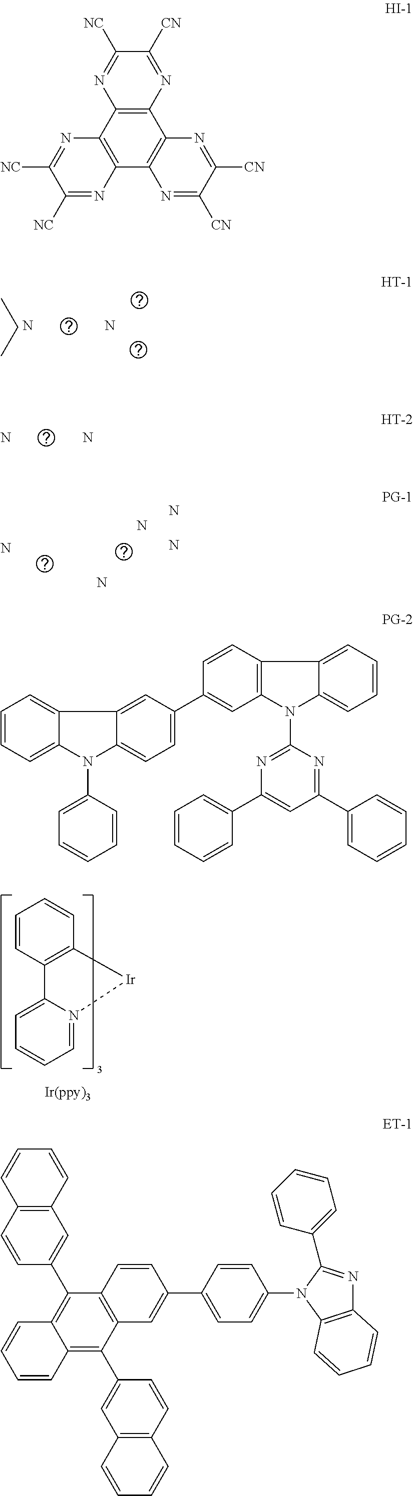

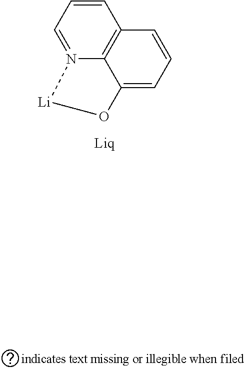

### Comparative 1

An organic EL device was manufactured in the same manner as in Example 1 except that the PG-2 (the second host material) was not used.

Table 1 shows the respective device arrangement of Example 1 and Comparative 1. The numerals in parentheses in Table 1 indicate the thicknesses of layers (unit: nm). The percentages in parentheses in Table 1 indicate the ratios of added components (mass %).

Table 2 shows results of measurement of the ionization potential of each of the first host material, the second host material and the hole transporting material. The ionization potential was measured under atmosphere with a photoelectron spectrometer (AC-1, manufactured by Riken Keiki Co., Ltd.). Specifically, a material was irradiated with light and the amount of electrons generated by charge separation was measured.

TABLE 1

| | Arrangement of Device |
|---|---|
| Ex. 1 | ITO/HI-1(30)/HT-1(100)/HT-2(70)/PG-1: PG-2: |
| | Ir(ppy)₃(40, 10%, 10%)/ET-1: Liq(25, 50%)/Liq(1)/Al(80) |
| Comp. 1 | ITO/HI-1(30)/HT-1(100)/HT-2(70)/PG-1: |
| | Ir(ppy)₃(40, 10%)/ET-1: Liq(25, 50%)/Liq(1)/Al(80) |

TABLE 2

| | Ionization Potential |
|---|---|
| | (eV) |
| HT-2 | 5.6 |
| PG-1 | 5.7 |
| PG-2 | 5.5 |

### Evaluation of Organic EL Device

Voltage was applied to the organic EL device of each of Example 1 and Comparative 1 to provide a current density of 10 mA/cm² and a voltage value (V) at that time was measured. An EL spectrum was measured with a spectral radiance meter (CS-1000, manufactured by KONICA MINOLTA). Chromaticity CIEₓ, CIE_{y} and current efficiency L/J (cd/A) were calculated from the obtained spectral-radiance spectrum. The results are shown in Table 3.

TABLE 3

| | Voltage | Current Density | Chromaticity (CIE) | | L/J |
|---|---|---|---|---|---|
| | (V) | (mA/cm²) | X | Y | (cd/A) |
| Ex. 1 | 4.35 | 10 | 0.296 | 0.643 | 66.1 |
| Comp. 1 | 3.97 | 10 | 0.296 | 0.644 | 53.2 |

In Example 1 according to the invention, the HT-2 of the second host material was lower in ionization potential than the compound HT-2 of the hole transporting layer and the PG-1 of the first host material. In view of the above, it has been found that the resulting organic EL device exhibited a higher luminous efficiency.

What is claimed is:

1. An organic electroluminescence device comprising:
an anode;
a cathode; and
at least hole transporting layer and emitting layer both being provided between the anode and the cathode, wherein
the hole transporting layer comprises a hole transporting material,
the emitting layer is provided adjacent to the hole transporting layer, and comprises a first host material, a second host material and a phosphorescent dopant material, and
an ionization potential IP(HT) of the hole transporting material, an ionization potential IP(h1) of the first host material and an ionization potential IP(h2) of the second host material satisfy a relationship represented by an expression 1 below.
IP(h1)>IP(HT)>IP(h2) Expression (1)

2. The organic electroluminescence devices according to claim 1, wherein a hole mobility of the second host material is higher than an electron mobility thereof.

3. The organic electroluminescence device according to claim 1, wherein the second host material is represented by a formula (1) below, 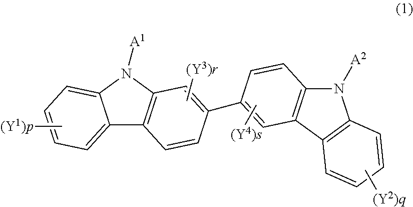
where:
A¹ and A² each represent a substituted or unsubstituted aromatic hydrocarbon group having 6 to 30 ring carbon atoms, a substituted or unsubstituted heterocyclic group having 1 to 30 ring carbon atoms, or a group represented by a formula (2) below,
—X-A³ (2)
where:
X is a single bond or a linking group, the linking group being a substituted or unsubstituted aromatic hydrocarbon group having 6 to 30 ring carbon atoms, a substituted or unsubstituted fused aromatic hydrocarbon group having 6 to 30 ring carbon atoms, a substituted or unsubstituted aromatic heterocyclic group having 2 to 30 ring carbon atoms, or a substituted or unsubstituted fused aromatic heterocyclic group having 2 to 30 ring carbon atoms;
A³ represents a substituted or unsubstituted nitrogen-containing heterocyclic group;
Y₁ to Y₄ each independently represent a hydrogen atom, a fluorine atom, a cyano group, a substituted or unsubstituted alkyl group having 1 to 20 carbon atoms, a substituted or unsubstituted alkoxy group having 1 to 20 carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 10 carbon atoms, a substituted or unsubstituted arylsilyl group having 6 to 30 carbon atoms, a substituted or unsubstituted aromatic hydrocarbon group having 6 to 30 ring carbon atoms, a substituted or unsubstituted fused aromatic hydrocarbon group having 6 to 30 ring carbon atoms, a substituted or unsubstituted aromatic heterocyclic group having 2 to 30 ring carbon atoms, a substituted or unsubstituted fused aromatic heterocyclic group having 2 to 30 ring carbon atoms, or a group represented by the formula (2);
adjacent ones of Y¹ to Y⁴ are allowed to be bonded to each other to form a ring structure;
any one of A¹, A² and Y¹ to Y⁴ contains the group represented by the formula (2);
p and q each represent an integer of 1 to 4 and r and s each represent an integer of 1 to 3; and
when each of p and q is an integer of 2 to 4 and each of r and s is an integer of 2 and 3, a plurality of Y¹ to Y⁴ are allowed to be the same or different.

4. The organic electroluminescence device according to claim 3, wherein in the formula (1) representing the second host material, at least one of A¹ and A² is the group represented by the formula (2) and X of the formula (2) represents a single bond.

5. The organic electroluminescence device according to claim 3, wherein in the formula (1) representing the second host material, A¹ is the group represented by the formula (2) and X of the formula (2) represents a single bond.

6. The organic electroluminescence device according to claim 1, further comprising an electron injecting layer being provided between the anode and the cathode adjacently to the cathode, the electron injecting layer comprising an organic metal complex.

7. The organic electroluminescence device according to claim 1, wherein an emission peak wavelength of the phosphorescent dopant material falls within a range from 480 nm to 570 nm.

8. The organic electroluminescence device according to claim 2, wherein the second host material is represented by a formula (1) below, 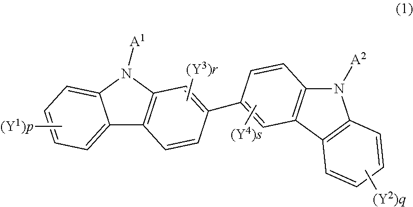
where:
A¹ and A² each represent a substituted or unsubstituted aromatic hydrocarbon group having 6 to 30 ring carbon atoms, a substituted or unsubstituted heterocyclic group having 1 to 30 ring carbon atoms, or a group represented by a formula (2) below,
—X-A³ (2)
where:
X is a single bond or a linking group, the linking group being a substituted or unsubstituted aromatic hydrocarbon group having 6 to 30 ring carbon atoms, a substituted or unsubstituted fused aromatic hydrocarbon group having 6 to 30 ring carbon atoms, a substituted or unsubstituted aromatic heterocyclic group having 2 to 30 ring carbon atoms, or a substituted or unsubstituted fused aromatic heterocyclic group having 2 to 30 ring carbon atoms;
A³ represents a substituted or unsubstituted nitrogen-containing heterocyclic group;
Y₁ to Y₄ each independently represent a hydrogen atom, a fluorine atom, a cyano group, a substituted or unsubstituted alkyl group having 1 to 20 carbon atoms, a substituted or unsubstituted alkoxy group having 1 to 20 carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 10 carbon atoms, a substituted or unsubstituted arylsilyl group having 6 to 30 carbon atoms, a substituted or unsubstituted aromatic hydrocarbon group having 6 to 30 ring carbon atoms, a substituted or unsubstituted fused aromatic hydrocarbon group having 6 to 30 ring carbon atoms, a substituted or unsubstituted aromatic heterocyclic group having 2 to 30 ring carbon atoms, a substituted or unsubstituted fused aromatic heterocyclic group having 2 to 30 ring carbon atoms, or a group represented by the formula (2);
adjacent ones of Y¹ to Y⁴ are allowed to be bonded to each other to form a ring structure;
any one of A¹, A² and Y¹ to Y⁴ contains the group represented by the formula (2);
p and q each represent an integer of 1 to 4 and r and s each represent an integer of 1 to 3; and
when each of p and q is an integer of 2 to 4 and each of r and s is an integer of 2 and 3, a plurality of Y¹ to Y⁴ are allowed to be the same or different.

9. The organic electroluminescence device according to claim 8, wherein in the formula (1) representing the second host material, at least one of A¹ and A² is the group represented by the formula (2) and X of the formula (2) represents a single bond.

10. The organic electroluminescence device according to claim 8, wherein in the formula (1) representing the second host material, A¹ is the group represented by the formula (2) and X of the formula (2) represents a single bond.

11. The organic electroluminescence device according to claim 8, further comprising an electron injecting layer being provided between the anode and the cathode adjacently to the cathode, the electron injecting layer comprising an organic metal complex.

12. The organic electroluminescence device according to claim 8, wherein an emission peak wavelength of the phosphorescent dopant material falls within a range from 480 nm to 570 nm.

13. The organic electroluminescence device according to claim 3, further comprising an electron injecting layer being provided between the anode and the cathode adjacently to the cathode, the electron injecting layer comprising an organic metal complex.

14. The organic electroluminescence device according to claim 3, wherein an emission peak wavelength of the phosphorescent dopant material falls within a range from 480 nm to 570 nm.
